(19) United States
(12) Patent Application Publication
(10) Pub. No.: US 2025/0004039 A1
(43) Pub. Date: Jan. 2, 2025

(54) METHOD AND APPARATUS FOR DETERMINING AND INFORMATION ABOUT CHARACTERISTICS OF ONE OR MORE DEVICES UNDER TEST, DUTs, USING A STATISTICALLY SIGNIFICANT DISSIMILARITY VALUE

(71) Applicant: Advantest Corporation, Tokyo (JP)

(72) Inventor: Jochen RIVOIR, Herrenberg (DE)

(21) Appl. No.: 18/760,029

(22) Filed: Jul. 1, 2024

Related U.S. Application Data
(63) Continuation of application No. PCT/EP2022/067632, filed on Jun. 27, 2022.

(30) Foreign Application Priority Data
Dec. 30, 2021 (EP) 21 218 398.2

(51) Int. Cl. G01R 31/28

(52) U.S. Cl. CPC G01R 31/2834

(57) ABSTRACT

Embodiments comprise methods and apparatuses for determining an information about characteristics of one or more devices under test (DUTs) using measurement data from an automated test equipment (ATE), the measurement data comprising a plurality of measurement results and information describing corresponding measurement conditions of the devices under test (DUTs).

### CROSS-REFERENCES TO RELATED APPLICATIONS

This application is a continuation of copending International Application No. PCT/EP2022/067632, filed Jun. 27, 2022, which is incorporated herein by reference in its entirety, and additionally claims priority from European Application No. EP 21 218 398.2, filed Dec. 30, 2021, which is incorporated herein by reference in its entirety.

### TECHNICAL FIELD

Embodiments according to the invention are related to methods and apparatuses for determining an information about characteristics of one or more devices under test, DUTs, using a statistically significant dissimilarity value.

### BACKGROUND OF THE INVENTION

In many cases, technical devices have to be tested, before being used in their respective target application. In order to provide cost-effective and reliable testing results, automated test equipments, ATEs, may be used.

However, especially for testing scenarios in which a plurality of parameters and large numbers of devices are to be tested, it may be difficult to process and/or to evaluate testing results.

Therefore, it is desired to get a concept which is applicable in such scenarios and which provides a better compromise between reliability, efficiency and costs.

This is achieved by the subject matter of the independent claims of the present application.

Further embodiments according to the invention are defined by the subject matter of the dependent claims of the present application.

### SUMMARY OF THE INVENTION

Embodiments according to the invention comprise a method for determining an information about characteristics of one or more devices under test, DUTs (e.g. an information ‘device under test shows differing behavior under these conditions with statistical significance’) using measurement data from an automated test equipment (ATE), the measurement data comprising a plurality of measurement results (e.g. target variable, e.g. T, e.g. ‘test passed’, e.g. ‘test failed’, e.g. continuous values, e.g. voltages or currents or signal characteristics) and information describing corresponding measurement conditions (e.g. describing conditions for corresponding independent variables, e.g. V=v, e.g. describing a condition that an independent variable V has the value v; e.g. measurement conditions under which the measurement results have been obtained) of the devices under test (DUTs).

The method comprises determining an information about, e.g. an information representing or describing, a conditional distribution (for example in case of Non-Boolean target variables a local conditional target distribution, e.g. pᵥ(t), or for example in case of a Boolean target variable a fraction of true target values pᵥ) of measurement results corresponding to a first subset of measurement conditions (e.g. for a given measurement condition or for a given, e.g. small, range of measurement conditions, e.g., wherein the independent variables take value V=v).

The method further comprises determining an information about, e.g. an information representing or describing, at least one sample distribution (for example in case of Non-Boolean target variables a plurality of empirical distributions qₛ or qₛ(t), or for example in case of Boolean target variables a probability q′), wherein the at least one sample distribution (e.g. one analytically determined, representative sample distribution in case of Boolean target variables or a plurality of empirical sample distributions in case of Non-Boolean target variables) is comparable, e.g. associated, with the conditional distribution (e.g. associated with a wider range of measurement conditions than the conditional distribution, e.g. comprising an equal or similar number of measurement results).

Moreover, the method comprises determining a statistically significant dissimilarity value (e.g. which indicates how a behavior of the DUT depends on the measurement condition; e.g. d(v); e.g. which characterizes a behavior of the DUT for a given measurement condition; e.g. describing a statistically significant dissimilarity between the conditional distribution and the one or more sample distributions; e.g. determining a dissimilarity threshold value, e.g. d(v), such that only a predetermined portion, e.g. 5%, of the sample distributions comprises a dissimilarity with respect to the conditional distribution which is smaller than or equal to the dissimilarity threshold value; e.g. determining a dissimilarity threshold value such that only a predetermined portion, e.g. 5%, of all instances of a sample distribution, e.g. of a binominal binomial distribution, comprise a dissimilarity with respect to the conditional distribution which is smaller than the or equal to the dissimilarity threshold value; e.g. determining a dissimilarity threshold value indicating whether the conditional distribution comprises indicating a minimum dissimilarity threshold between the conditional distribution and the sample distributions, excluding a predetermined fraction of the sample distributions which are most similar to the conditional distribution) using the information about, e.g. the information representing or describing, the conditional distribution and using the information about, e.g. the information representing or describing, the at least one sample distribution, wherein the information about the characteristics of the one or more DUTs comprises the statistically significant dissimilarity value or is based on the statistically significant dissimilarity value.

The inventors recognized that DUT characteristics may be determined or evaluated robustly and efficiently, based on measurement data comprising a plurality of measurement results and information describing corresponding measurement conditions, by using, for example comparing, an information about a conditional distribution and information about at least one sample distribution.

In simple words, and as an example, the inventors recognized that in order to evaluate or to classify measurement results corresponding to a first subset of measurement conditions, an information about a conditional distribution thereof may be determined. In order to allow for a robust and reliable evaluation, this conditional distribution may, for example, be compared to at least one sample distribution. In simple words, out of the plurality of ATE test cases (e.g. comprising results and corresponding conditions), one or more times, test cases may, e.g. randomly, be chosen and one or more sample distributions thereof may be determined. In order to keep the one or more sample distribution comparable to the conditional distribution, a respective sample distribution may be associated with a similar or even equal number of test cases than the conditional distribution.

Now, the one or each of the sample distributions may, for example, be compared with the conditional distribution. Simply speaking, the comparison may answer the question whether the conditional distribution is similar to a sample distribution or diverges significantly (wherein, as an example, the sample distribution is based on randomly drawn test cases). Hence, based on the comparison not only can, for example, a difference be detected but an information about a statistical significance of the difference may be provided as well.

The inventors recognized that a dissimilarity value may allow to provide a good metric for such a comparison. A statistically significant dissimilarity value may hence be determined based on the one ore a plurality of comparisons between the conditional distribution and the one or more sample distributions.

According to further embodiments of the invention, the sample distribution is an empirical distribution, and determining the information about, e.g. representing or describing, the at least one sample distribution comprises determining an information about (e.g. representing or describing) a plurality of empirical distributions, e.g. qₛ, of measurement results of a plurality of subsets of the measurement data (e.g. of measurement results obtained over a large range of measurement conditions or obtained over a random range of measurement conditions).

Furthermore, a number of measurement results considered for the determination of the information about a respective empirical distribution, e.g. of the information about each of the empirical distributions, is associated with (e.g. corresponds to, e.g. deviates by no more than 10% or 20% from; e.g. is equal to) a number of measurement results considered for the determination of the information about the conditional distribution, and the measurement results of a respective subset of the measurement data is a set of randomly or pseudo randomly, e.g. or arbitrarily, selected measurement results of the measurement data.

The method further comprises determining a plurality of dissimilarity measures, e.g. Kullback-Leibler divergences, between the conditional distribution and respective, e.g. each of the, empirical distributions, using the information about the conditional distribution (e.g. the conditional distribution itself) and using the information about the respective empirical distribution (e.g. the empirical distribution itself). In addition, the method further comprises determining the statistically significant dissimilarity value, e.g. d(v), using the plurality of dissimilarity measures.

According to further embodiments of the invention, the statistically significant dissimilarity value (e.g. d(v), e.g. which indicates how a behavior of the DUT depends on the measurement condition; e.g. d(v), e.g. which characterizes a behavior of the DUT for a given measurement condition, e.g. describing a statistically significant dissimilarity between the conditional distribution and the one or more sample distributions; e.g. determining a dissimilarity threshold value, e.g. d(v), such that only a predetermined portion, e.g. 5%, of the sample distributions comprises a dissimilarity with respect to the conditional distribution which is smaller than or equal to the dissimilarity threshold value; e.g. determining a dissimilarity threshold value such that only a predetermined portion, e.g. 5%, of all instances of a sample distribution, e.g. of a binominal binomial distribution, comprise a dissimilarity with respect to the conditional distribution which is smaller than the or equal to the dissimilarity threshold value; e.g. determining a dissimilarity threshold value indicating whether the conditional distribution comprises indicating a minimum dissimilarity threshold between the conditional distribution and the sample distributions, excluding a predetermined fraction of the sample distributions which are most similar to the conditional distribution) is associated with a quantile (e.g. a percentile, e.g. the lower 1-C percentile, e.g. with C=95%) of a distribution of the dissimilarity measures.

According to further embodiments of the invention, the method further comprises determining a cumulative distribution, e.g. CDF, of the plurality of dissimilarity measures and determining the statistically significant dissimilarity value, e.g. d(v), such that only a predetermined portion of the empirical distributions comprises a dissimilarity measure with respect to the conditional distribution, which is smaller than or equal to the statistically significant dissimilarity value, e.g., such that only a predetermined portion of the dissimilarity measures between respective empirical distributions and the conditional distribution are smaller than or equal to the statistically significant dissimilarity value.

According to further embodiments of the invention, the method further comprises extrapolating the cumulative distribution and/or interpolating the cumulative distribution in order to determine the statistically significant dissimilarity value, e.g. d(v).

According to further embodiments of the invention, the method further comprises selecting a dissimilarity measure, e.g. Dₛ, of the plurality of dissimilarity measures, wherein the selected dissimilarity measure comprises a smallest deviation to the statistically significant dissimilarity value, e.g. d(v), out of the plurality of dissimilarity measures and the method comprises determining a mean value of an empirical distribution corresponding to the selected dissimilarity measure.

In addition, the method comprises determining a mean value, e.g. pᵥ, of the conditional distribution of the measurement results corresponding to the first subset of measurement conditions and determining a mean-aligned dissimilarity measure (e.g. Dₛ′; e.g. using the mean value of the empirical distribution corresponding to the selected dissimilarity measure; e.g. using the mean value (e.g. pᵥ) of the conditional distribution of the measurement results corresponding to the first subset of measurement conditions) between the conditional distribution and the empirical distribution corresponding to the selected dissimilarity measure.

The method further comprises determining an information about a normalized dissimilarity

$${μ}^{′} = \frac{{D}_{{S}^{′}} - {\overline{D}}_{{S}^{′}}}{{D}_{{S}^{′}}} ,$$

dissimilarity measure, e.g. Dₛ′, between the conditional distribution and the empirical distribution corresponding to the selected dissimilarity measure, wherein the normalized dissimilarity fraction optionally comprises an information about an amount of the dissimilarity measure that is associated with differing means between the conditional distribution and the empirical distribution corresponding to the lowest dissimilarity measure.

Furthermore, the information about the characteristics of the one or more DUTs comprises the

$${μ}^{′} = \frac{{D}_{{S}^{′}} - {\overline{D}}_{{S}^{′}}}{{D}_{{S}^{′}}} , .$$

information about the normalized dissimilarity fraction, e.g.

According to further embodiments of the invention, the method further comprises selecting a dissimilarity measure, e.g. Dₛ, of the plurality of dissimilarity measures, wherein the selected dissimilarity measure comprises a smallest deviation to the statistically significant dissimilarity value, e.g. d(v), out of the plurality of dissimilarity measures, wherein the information about the characteristics of the one or more DUTs comprises an information, e.g. the selected dissimilarity measure, about the selected dissimilarity measure.

According to further embodiments of the invention, the method further comprises determining a mean value, e.g. pᵥ, of the conditional distribution of the measurement results corresponding to the first subset of measurement conditions and optionally determining a mean value, e.g. Q, of an overall distribution of the measurement results.

In addition, the method comprises determining a mean-aligned dissimilarity measure (e.g. D; e.g. using the mean value (e.g. pᵥ) of the conditional distribution of the measurement results corresponding to the first subset of measurement conditions; e.g. using the mean value (e.g. Q) of the overall distribution of the measurement results) between the conditional distribution and an overall distribution of the measurement results and the method comprises determining a dissimilarity measure, e.g. D, between the conditional distribution and the overall distribution.

Furthermore, the method comprises determining an information about a normalized dissimilarity fraction, e.g.

$$μ = \frac{D - \overline{D}}{D} ,$$

using the mean-aligned dissimilarity measure, e.g. D_{S′}, and using the dissimilarity measure, e.g. D_{S′}, between the conditional distribution and the overall distribution, wherein optionally the normalized dissimilarity fraction comprises an information about an amount of the dissimilarity measure that is associated with differing means between the conditional distribution and the overall distribution.

Furthermore, the information about the characteristics of the one or more DUTs comprises the information about the normalized dissimilarity fraction, e.g. μ.

According to further embodiments of the invention, the method further comprises a binning of measurement data values, wherein the binning is performed based on a parameter a, which influences how many measurement data values (e.g. hits, e.g. values of a target variable, e.g. of target variable t, e.g. values of an independent variable, e.g. of independent variable v) are quantized, e.g. binned, to a value bin, e.g. a quantization level.

Furthermore, the measurement data, e.g. the measurement conditions and/or the measurement results, comprises a continuous variable, and the method further comprises quantizing a value of the continuous variable into a value bin.

Alternatively or in addition, the measurement data comprises a categorical variable and a respective categorical variable value is associated with, e.g. is binned to, e.g. is addressed with, one respective value bin.

Alternatively or in addition, the measurement data comprises a discrete variable, and the discrete variable comprises M different values, and the values of the discrete variable are quantized to at most M value bins.

According to further embodiments of the invention, the measurement data comprises a number of data sets (e.g. a number of measurement results and corresponding measurement conditions; e.g. a number of test cases) of DUT tests. Furthermore, the number of value bins, e.g. quantization levels, of the measurement data is determined using the number of data sets and using a partitioning (e.g. a division by) based on a number of categorical variables value combinations and/or using the number of data sets and using a partitioning (e.g. a division by) based on the parameter a; and/or using the number of data sets and using a partitioning (e.g. using a square root) based on a number of continuous and discrete variables; and/or using the number of data sets using a partitioning (e.g. using a square root) based on a number of continuous variables, e.g., wherein a plurality of partitionings may be combined in a joint processing or a combined processing.

According to further embodiments of the invention, the measurement data comprises the measurement results (e.g. target variable values; e.g. target variables and values thereof) and values of one or more corresponding independent variables and the method further comprises determining the first subset of measurement conditions, such that measurement conditions of the first subset are neighbored, e.g. in the neighborhood of the first measurement condition; e.g. are nearest neighbors of a first measurement condition; e.g. neighbored to an independent variable value.

According to further embodiments of the invention, the measurement data comprises the measurement results, e.g. target variables and values thereof, and values of one or more corresponding independent variables, and the method further comprises binning values of the measurement data, wherein measurement results and/or independent variable values of the measurement data are quantized, e.g. binned, to value bins.

The method further comprises determining an information, e.g. a probability; e.g. Q(t), about an overall distribution of the measurement results based on measurement results of respective, e.g. of all, value bins.

In addition, the method comprises determining an information about a conditional distribution of measurement results of the first subset of measurement conditions, wherein the first subset of measurement conditions is associated with the independent variable values of a respective value bin and the method comprises determining a number, e.g. n(v), of measurement results corresponding to the first subset of measurement conditions.

Moreover, the method comprises determining an information about a plurality of empirical distributions, e.g. qₛ, of measurement results of a plurality of subsets of the measurement data, wherein a number of measurement results considered for the determination of the information about a respective empirical distribution is equal to the number, e.g. n(v), of measurement results of (e.g. corresponding to, e.g. associated to) the first subset of measurement conditions, and wherein the measurement results of a respective subset of the measurement data are a set of randomly or pseudo randomly selected measurement results of the measurement data.

The method further comprises determining a plurality of dissimilarity measures, e.g. Kullback-Leibler divergences, between the conditional distribution and respective, e.g. each of the, empirical distributions using the information about the conditional distribution, e.g. the conditional distribution itself, and using the information about the respective empirical distribution.

The method further comprises determining a cumulative distribution, e.g. CDF, of the plurality of dissimilarity measures, and determining the statistically significant dissimilarity value, e.g. d(v), such that only a predetermined portion of the empirical distributions comprises a dissimilarity measure with respect to the conditional distribution, which is smaller than or equal to the statistically significant dissimilarity value and the method comprises selecting a dissimilarity measure, e.g. Dₛ, of the plurality of dissimilarity measures, wherein the selected dissimilarity measure comprises a smallest deviation to the statistically significant dissimilarity value, e.g. d(v), out of dissimilarity measures of the plurality of dissimilarity measures.

Furthermore, the method comprises determining a mean value of the empirical distribution corresponding to the selected dissimilarity measure and determining a mean value, e.g. pᵥ, of the conditional distribution of the measurement results corresponding to the first subset of measurement conditions and the method comprises determining a mean-aligned dissimilarity measure (e.g. Dₛ′; e.g. using the mean value of the empirical distribution corresponding to the selected dissimilarity measure; e.g. using the mean value (e.g. pᵥ) of the conditional distribution of the measurement results corresponding to the first subset of measurement conditions) between the conditional distribution and the empirical distribution corresponding to the selected dissimilarity measure.

In addition, the method comprises determining an information about a normalized dissimilarity

$${μ}^{′} = \frac{{D}_{{S}^{′}} - {\overline{D}}_{{S}^{′}}}{{D}_{{S}^{′}}} ,$$

fraction, e.g. using the mean-aligned dissimilarity measure, e.g. Dₛ′, and using the dissimilarity measure, e.g. Dₛ, between the conditional distribution and the empirical distribution corresponding to the selected dissimilarity measure, wherein optionally the normalized dissimilarity fraction comprises an information about an amount of the dissimilarity measure that is associated with differing means between the conditional distribution and the empirical distribution corresponding to the lowest dissimilarity measure.

Moreover, the information about the characteristics of the DUTs comprises the information about the normalized dissimilarity fraction, e.g.

$${μ}^{′} = \frac{{D}_{{S}^{′}} - {\overline{D}}_{{S}^{′}}}{{D}_{{S}^{′}}} .$$

According to further embodiments of the invention, the measurement data comprises the measurement results, e.g. target variables and values thereof, and values of one or more corresponding independent variables.

Furthermore, the method comprises binning values of the measurement data, wherein measurement results and/or independent variable values of the measurement data are quantized, e.g. binned, to value bins and the method comprises determining an information, e.g. Q(t), about an overall distribution of the measurement results based on measurement results of respective, e.g. of all, value bins.

In addition, the method comprises determining an information about a conditional distribution of measurement results of the first subset of measurement conditions wherein the first subset of measurement conditions is associated with the independent variable values of a respective value bin and the method comprises determining a number, e.g. n(v), of measurement results corresponding to the first subset of measurement conditions.

Moreover, the method comprises determining an information about a plurality of empirical distributions, e.g. qₛ, of measurement results of a plurality of subsets of the measurement data, wherein a number of measurement results considered for the determination of the information about a respective empirical distribution is equal to the number of measurement results of (e.g. corresponding to, e.g. associated to) the first subset of measurement conditions. In addition, the measurement results of a respective subset of the measurement data are a set of randomly or pseudo randomly selected measurement results of the measurement data.

The method further comprises determining a plurality of dissimilarity measures, e.g. Kullback-Leibler divergences, between the conditional distribution and respective, e.g. each of the, empirical distributions using the information about the conditional distribution, e.g. the conditional distribution itself, and using the information about the respective empirical distribution and the method comprises determining a cumulative distribution, e.g. CDF, of the plurality of dissimilarity measures.

In addition, the method comprises determining the statistically significant dissimilarity value, e.g. d(v), such that only a predetermined portion of the empirical distributions comprises a dissimilarity measure with respect to the conditional distribution, which is smaller than or equal to the statistically significant dissimilarity value and the method comprises selecting a dissimilarity measure, e.g. Dₛ, of the plurality of dissimilarity measures, wherein the selected dissimilarity measure comprises a smallest deviation to the statistically significant dissimilarity value, e.g. d(v), out of dissimilarity measures of the plurality of dissimilarity measures, wherein the information about the characteristics of the DUTs comprises the selected dissimilarity measure.

According to further embodiments of the invention, a plurality of statistically significant dissimilarity values, e.g. d(v), and/or a plurality of normalized dissimilarity fractions, e.g. u′; e.g. u, are determined for different subsets of measurement conditions corresponding to respective value bins.

According to further embodiments of the invention, the method further comprises obtaining, e.g. receiving, or determining, based on the measurement data, an information, e.g. Q, about an overall distribution of the measurement results and comparing the information about the overall distribution and the information about the conditional distribution, e.g. determining whether pᵥ<Q or pᵥ>Q holds, wherein the information, e.g. q′, about the at least one sample distribution is determined based on the comparison of the information, e.g. Q, about the overall distribution and the information, e.g. pᵥ, about the conditional distribution (e.g. determining q′ according to the largest k′ fulfilling Pr(X≤k′)≤1-C in case pᵥ<Q, or e.g. determining q′ according to the smallest k′ fulfilling Pr(X≤k′)≤C in case pᵥ≥Q).

The method further comprises comparing the information about the overall distribution, the information about the conditional distribution and the information about the at least one sample distribution (e.g. determining whether pᵥ<q′<Q or q′<p><Q; or Q≤pᵥ≤q′ or Q<q′<pᵥ) and determining the statistically significant dissimilarity value, e.g. d(v), based on, e.g. in dependence of, the comparison of the information about the overall distribution, the information about the conditional distribution and the information about the at least one sample distribution (e.g. such that

$$d ( v ) = log ( \frac{{p}_{v}}{{q}^{′}} ) + ( 1 - {p}_{v} ) log ( \frac{1 - {p}_{v}}{1 - {q}^{′}} )$$

if pᵥ<q′<Q or d(v)=0 if q′<p><Q; or d(v)=0 if Q≤pᵥ≤q′ or

$$d ( v ) = log ( \frac{{p}_{v}}{{q}^{′}} ) + ( 1 - {p}_{v} ) log ( \frac{1 - {p}_{v}}{1 - {q}^{′}} )$$

According to further embodiments of the invention, the measurement data comprises the measurement results, e.g. target variables and/or values thereof, and corresponding independent variables values (e.g. independent variables values v; e.g. of corresponding independent variables V; e.g. and also a definition of corresponding independent variables; e.g. jointly represented by V), and the method further comprises binning values of the measurement data, wherein measurement results and/or independent variable values of the measurement data are binned, e.g. quantized, to value bins and wherein the measurement results are Boolean target variables having measurement results of true or false.

The method further comprises determining an information Q about an overall distribution of the measurement results, wherein information Q is a probability for a measurement result to be true, or a probability for a measurement result to be false, based on the overall measurement results of the measurement data, wherein the information Q may, for example, represent a fraction of measurement results which comprise a “true” value within a total amount of measurement results.

Furthermore, the method comprises determining a number n(v) of measurement results corresponding to the first subset of measurement conditions, e.g. corresponding to independent variable values v, wherein the first subset of measurement conditions is associated with the independent variable values of a respective value bin and the method comprises determining an information pᵥ about a conditional distribution of measurement results corresponding to the first subset of measurement conditions, wherein the information pᵥ is a probability for a measurement result to be true based on the measurement results corresponding to the first subset of measurement conditions, or wherein the information pᵥ is a probability for a measurement result to be false based on the measurement results corresponding to the first subset of measurement conditions.

Moreover, the method comprises determining whether pᵥ<Q and/or whether pᵥ>Q holds and/or whether pᵥ=Q holds and/or whether pᵥ≥Q holds.

In case pᵥ<Q holds, the method comprises determining an information q′ about a sample distribution, using q′=k′/n(v), wherein k′ is a largest number of true test cases fulfilling Pr (X≤k′)≤1-C, wherein C is a confidence value, with Pr (X≤k′)≤1-C being the condition that the probability, Pr, of having less than or equal to k′ positive measurement results X when choosing n(v) arbitrary measurement results from the measurement data (e.g. results from an overall set of measurement results; e.g. considering the above mentioned information Q; wherein the method may, for example, determine k′ using an evaluation of a binominal distribution using a number n(v) of samples and an individual probability defined by Q) is equal or less than confidence C subtracted from 1, and in case pᵥ<q′<Q holds, determining the statistically significant dissimilarity value d(v) using

$$d ( v ) = log ( \frac{{p}_{v}}{{q}^{′}} ) + ( 1 - {p}_{v} ) log ( \frac{1 - {p}_{v}}{1 - {q}^{′}} ) ,$$

and/or in case q′≤pᵥ<Q holds setting the statistically significant dissimilarity value d(v) to d(v)=0.

Alternatively or in addition, in case pᵥ>Q holds, the method comprises determining an information q′ about a sample distribution, using q′=k′/n(v) according to the smallest k′ fulfilling Pr (X≤k′)≤C, with Pr (X≤k′)≤C being the condition that the probability, Pr, of having less than or equal to k′ positive measurement results X when choosing n(v) arbitrary measurement results from the measurement data (e.g. results from an overall set of measurement results; e.g. considering the above mentioned information Q; wherein the method may, for example, determine k′ using an evaluation of a binominal distribution using a number n(v) of samples and an individual probability defined by Q) is equal or less than the confidence C, and in case Q≤pᵥ≤q′ holds setting the statistically significant dissimilarity value d(v) to d(v)=0, or in case Q<q′<pᵥ holds, determining the statistically significant dissimilarity value d(v) using

$$d ( v ) = log ( \frac{{p}_{v}}{{q}^{′}} ) + ( 1 - {p}_{v} ) log ( \frac{1 - {p}_{v}}{1 - {q}^{′}} ) .$$

Alternatively or in addition, in case pᵥ=Q holds, the method comprises setting the statistically significant dissimilarity value d(v) to d(v)=0.

According to further embodiments of the invention, the method further comprises determining a plurality of respective statistically significant dissimilarity values, e.g. d(v), for different subsets of measurement conditions corresponding to, e.g. binned to, respective value bins.

According to further embodiments of the invention, the method further comprises extending the measurement data using the statistically significant dissimilarity value, e.g. d(v), wherein the extended measurement data is a combination of the measurement data itself and associated measurement data meta information, e.g. an extension information, wherein the associated measurement data meta information is determined based on the statistically significant dissimilarity value, e.g. d(v), and wherein the measurement data meta information comprises an information about statistically significant dissimilarities between measurement results corresponding to the first subset of measurement conditions and overall measurement results or between measurement results corresponding to the first subset of measurement conditions and measurement results of a selected sample distribution.

According to further embodiments of the invention, the method further comprises determining a normalized dissimilarity fraction, e.g. u, or u′ using a mean-aligned dissimilarity measure, e.g. D; and using a dissimilarity measure, e.g. a Kullback-Leibler divergence; e.g. D, between the conditional distribution, e.g. pᵥ (t), and an overall distribution of the measurement results, wherein the normalized dissimilarity fraction comprises an information about an amount of the dissimilarity measure that is associated with differing means between the conditional distribution and the overall distribution (e.g. such that, for example, the normalized dissimilarity fraction indicates whether the dissimilarity measure is strongly affected by different means of the conditional distribution and of the overall distribution or not), or using a dissimilarity measure between the conditional distribution and a sample distribution, e.g. an empirical distribution, of the measurement results, wherein the normalized dissimilarity fraction comprises an information about an amount of the dissimilarity measure that is associated with differing means between the conditional distribution and the sample distribution.

Furthermore, the measurement data meta information comprises an information about the normalized dissimilarity fraction (e.g., hence comprising an information about an amount of the dissimilarity measure that is associated with differing means between the conditional distribution and the overall distribution or between the conditional distribution and the sample distribution).

According to further embodiments of the invention, the method further comprises visualizing, e.g. plotting, the measurement data and a measurement data meta information, which may, for example, also be considered an extension information, that is based on the statistically significant dissimilarity value, e.g. d(v).

Furthermore, a visualization, e.g. a plot, of the, e.g. extended, measurement data comprises a representation of the measurement results over the measurement conditions or over corresponding independent variables, e.g. or over corresponding independent variable values the visualization (e.g. a representation of the measurement results) comprises highlights, wherein the highlights are dependent on (e.g. based on; e.g. associated with) the measurement data meta information (e.g. the corresponding measurement data meta information of the respective measurement results), such that measurement results of corresponding conditional distributions deviating statistically significantly from an overall distribution of the measurement results, or deviating from a sample distribution, e.g. an empirical distribution, of the measurement results, are highlighted; and/or such that areas of the visualization associated with measurement results of corresponding conditional distributions deviating statistically significantly from an overall distribution of the measurement results, or deviating from a sample distribution, e.g. an empirical distribution, of the measurement results, are highlighted.

According to further embodiments of the invention, the highlighting comprises coloring a background of the plot, wherein a saturation of the coloring is determined according to the statistically significant dissimilarity value.

According to further embodiments of the invention, a color of the coloring is determined according to a normalized dissimilarity fraction. Alternatively or in addition, a color of the coloring is determined according to a comparison of an information about an overall distribution of the measurement results and the information about the conditional distribution. Alternatively or in addition, a color of the coloring is determined according to a comparison of an information about a sample distribution of the measurement results and the information about the conditional distribution.

According to further embodiments of the invention, the method further comprises visualizing the measurement data using the statistically significant dissimilarity value.

Further embodiments according to the invention comprise a computer program for performing the method according to any of the preceding claims when the computer program runs on a computer.

Further embodiments according to the invention comprise an apparatus for determining an information about characteristics of one or more devices under test (DUTs) (e.g. an information ‘device under test shows differing behavior under these conditions with statistical significance’) using measurement data from an automated test equipment (ATE), the measurement data comprising a plurality of measurement results (e.g. target variable, e.g. T, e.g. ‘test passed’, e.g. ‘test failed’, e.g. continuous values, e.g. voltages or currents or signal characteristics) and information describing corresponding measurement conditions (e.g. describing conditions for corresponding independent variables, e.g. V=v, e.g. describing a condition that an independent variable V has the value v; e.g. measurement conditions under which the measurement results have been obtained) of the devices under test (DUTs).

The apparatus is configured to determine an information about, e.g. an information representing or describing, a conditional distribution (for example in case of Non-Boolean target variables a local conditional target distribution, e.g. pᵥ (t), or for example in case of a Boolean target variable a fraction of true target values pᵥ) of measurement results corresponding to a first subset of measurement conditions (e.g. for a given measurement condition or for a given, e.g. small, range of measurement conditions, e.g., wherein the independent variables take value V=v).

Furthermore, the apparatus is configured to determine an information about, e.g. an information representing or describing, at least one sample distribution (for example in case of Non-Boolean target variables a plurality of empirical distributions qₛ or qₛ (t), or for example in case of Boolean target variables a probability q′), wherein the at least one sample distribution (e.g. one analytically determined, representative sample distribution in case of Boolean target variables or a plurality of empirical sample distributions in case of Non-Boolean target variables) is comparable, e.g. associated, with the conditional distribution (e.g. associated with a wider range of measurement conditions than the conditional distribution, e.g. comprising an equal or similar number of measurement results).

Moreover, the apparatus is configured to determine a statistically significant dissimilarity value (e.g. which indicates how a behavior of the DUT depends on the measurement condition; e.g. d(v); e.g. which characterizes a behavior of the DUT for a given measurement condition; e.g. describing a statistically significant dissimilarity between the conditional distribution and the one or more sample distributions!; e.g. determining a dissimilarity threshold value, e.g. d(v), such that only a predetermined portion, e.g. 5%, of the sample distributions comprises a dissimilarity with respect to the conditional distribution which is smaller than or equal to the dissimilarity threshold value; e.g. determining a dissimilarity threshold value such that only a predetermined portion, e.g. 5%, of all instances of a sample distribution, e.g. of a binominal binomial distribution, comprise a dissimilarity with respect to the conditional distribution which is smaller than the or equal to the dissimilarity threshold value; e.g. determining a dissimilarity threshold value indicating whether the conditional distribution comprises indicating a minimum dissimilarity threshold between the conditional distribution and the sample distributions, excluding a predetermined fraction of the sample distributions which are most similar to the conditional distribution) using the information about, e.g. the information representing or describing, the conditional distribution and using the information about, e.g. the information representing or describing, the at least one sample distribution.

In addition, the information about the characteristics of the one or more DUTs comprises the statistically significant dissimilarity value or is based on the statistically significant dissimilarity value (e.g., wherein the apparatus is configured to determine the statistically significant dissimilarity value as the information about the characteristics of the one or more DUTs or wherein the apparatus is configured to determine the information about the characteristics of the one or more DUTs based on the statistically significant dissimilarity value).

The apparatus as described above is based on the same considerations as the above-described method. The apparatus can, by the way, be completed with all features and functionalities, which are also described with regard to the apparatus.

### BRIEF DESCRIPTION OF THE DRAWINGS

The drawings are not necessarily to scale, emphasis instead generally being placed upon illustrating the principles of the invention. In the following description, various embodiments of the invention are described with reference to the following drawings, in which:

FIG. 1 shows a schematic block diagram of a method according to embodiments of the invention;

FIG. 2 shows a schematic block diagram of a method with optional features according to embodiments of the invention;

FIG. 3 shows a schematic block diagram of a method with further optional features according to embodiments of the invention;

FIG. 4 shows a schematic block diagram of another method with optional features according to embodiments of the invention;

FIG. 5 shows a block diagram of a further method according to embodiments of the invention;

FIG. 6 shows a block diagram of a method comprising comparison steps according to embodiments of the invention;

FIG. 7 shows a block diagram of a further method comprising comparison steps according to embodiments of the invention;

FIG. 8 shows a schematic block diagram for an extension of measurement data according to embodiments of the invention;

FIG. 9 shows a schematic view on an apparatus according to embodiments of the invention;

FIG. 10 shows an example for a scatter plot with Boolean target variable (true: error, blue: no error);

FIG. 11A-11C shows an example for a statistically significant divergence according to embodiments of the invention;

FIG. 12A-12D shows an example an example for probability densities according to embodiments of the invention;

FIG. 13 shows examples according to embodiments for highlighted areas of independent variable(s) for various plot types where the local target distribution differs from its overall distribution according to embodiment of the invention;

FIG. 14 shows an example of a scatter plot with Boolean target variable according to embodiments of the invention;

FIG. 15A-15B shows an example for a highlighting with saturation according to embodiments of the invention; and

FIG. 16A-16E shows several plot examples according to embodiments of the invention.

### DETAILED DESCRIPTION OF THE EMBODIMENTS

Equal or equivalent elements or elements with equal or equivalent functionality are denoted in the following description by equal or equivalent reference numerals even if occurring in different figures.

In the following description, a plurality of details is set forth to provide a more throughout explanation of embodiments of the present invention. However, it will be apparent to those skilled in the art that embodiments of the present invention may be practiced without these specific details. In other instances, well-known structures and devices are shown in block diagram form rather than in detail in order to avoid obscuring embodiments of the present invention. In addition, features of the different embodiments described herein after may be combined with each other, unless specifically noted otherwise.

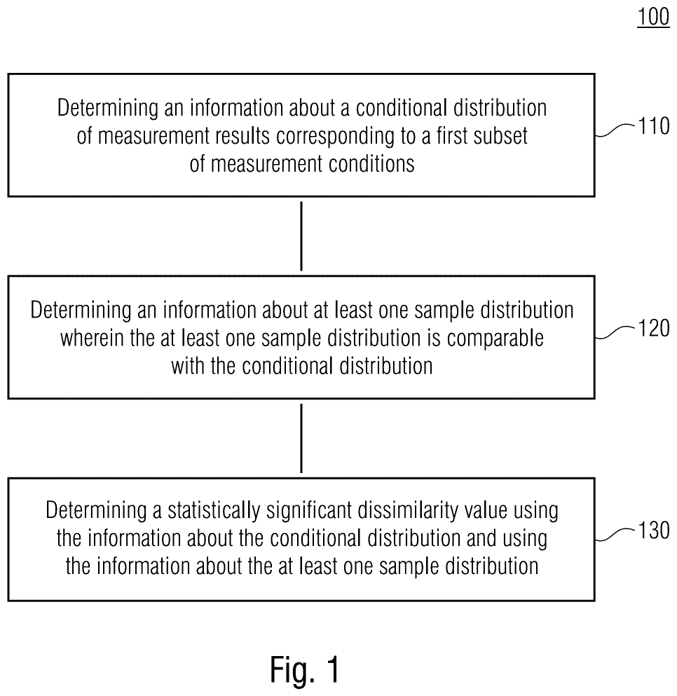

FIG. 1 shows a schematic block diagram of a method according to embodiments of the invention. Method 100 is a method for determining an information about characteristics of one or more devices under test (DUTs) using measurement data from an automated test equipment (ATE), the measurement data comprising a plurality of measurement results and information describing corresponding measurement conditions of the devices under test (DUTs).

Method 100 comprises determining 110 an information about a conditional distribution of measurement results corresponding to a first subset of measurement conditions, determining 120 an information about at least one sample distribution wherein the at least one sample distribution is comparable with the conditional distribution and determining 130 statistically significant dissimilarity value using the information about the conditional distribution and using the information about the at least one sample distribution. In addition, the information about the characteristics of the one or more DUTs comprises the statistically significant dissimilarity value or is based on the statistically significant dissimilarity value.

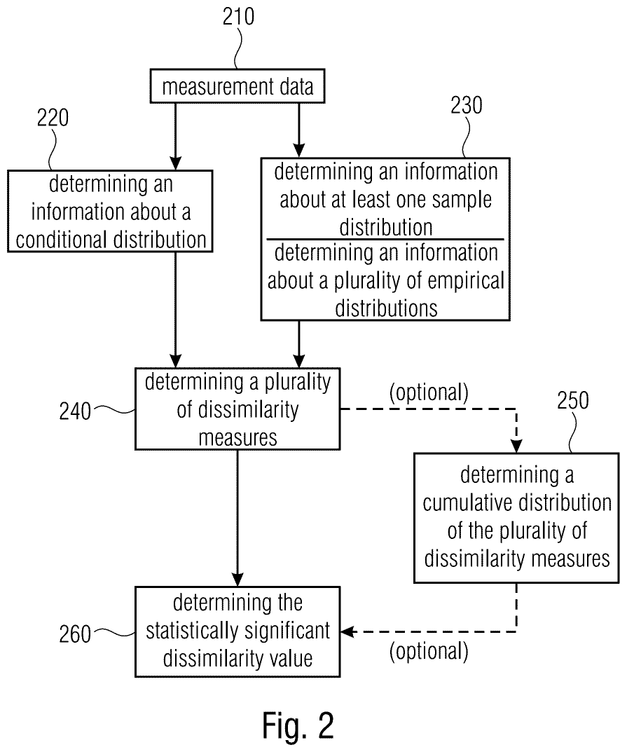

FIG. 2 shows a schematic block diagram of a method with optional features according to embodiments of the invention. Based on measurement data 210 from an automated test equipment (ATE), the measurement data comprising a plurality of measurement results and information describing corresponding measurement conditions, an information about a conditional distribution of measurement results corresponding to a first subset of measurement conditions (block 220) and an information about at least one sample distribution, wherein the at least one sample distribution is comparable with the conditional distribution (block 230), is determined.

As an optional feature, the determination of the information about the at least one sample distribution may comprise determining an information about a plurality of empirical distributions of measurement results of a plurality of subsets of the measurement data, wherein a number of measurement results considered for the determination of the information about a respective empirical distribution is associated with a number of measurement results considered for the determination of the information about the conditional distribution.

Furthermore, the measurement results of a respective subset of the measurement data may, for example, be a set of randomly or pseudo randomly selected measurement results of the measurement data.

As another optional feature, the method may comprise determining a plurality of dissimilarity measures between the conditional distribution and respective empirical distributions, using the information about the conditional distribution and using the information about the respective empirical distribution (block 240).

As an example, the method further comprises determining the statistically significant dissimilarity value using the plurality of dissimilarity measures (block 260).

Optionally, the statistically significant dissimilarity value may be associated with a quantile of a distribution of the dissimilarity measures.

As another optional feature, the method may further comprise determining a cumulative distribution of the plurality of dissimilarity measures and determining the statistically significant dissimilarity value, such that only a predetermined portion of the empirical distributions comprises a dissimilarity measure with respect to the conditional distribution, which is smaller than or equal to the statistically significant dissimilarity value (block 250).

Optionally, the method may further comprise extrapolating the cumulative distribution; and/or interpolating the cumulative distribution in order to determine the statistically significant dissimilarity value (e.g. in block 250).

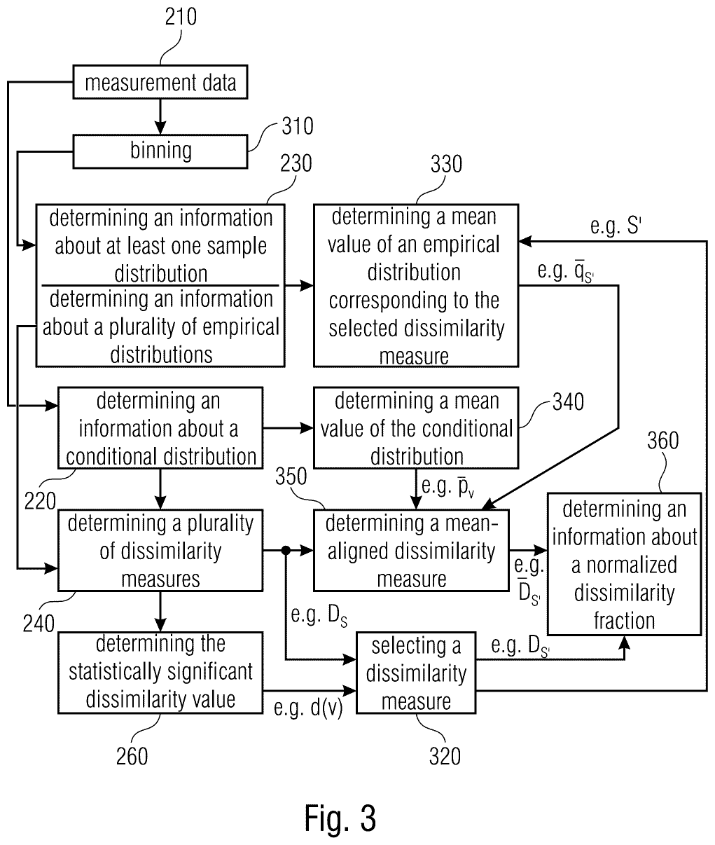

FIG. 3 shows a schematic block diagram of a method with further optional features according to embodiments of the invention.

As shown in FIG. 3, based on measurement data 210 from the automated test equipment (ATE), the measurement data comprising a plurality of measurement results, an optional binning 310 may be performed.

The binning may be performed based on a parameter a (not shown), which influences how many measurement data values are quantized to a value bin. Furthermore, the measurement data 310 may optionally comprise a continuous variable, and the method may further comprises quantizing a value of the continuous variable into a value bin. Alternatively or in addition, the measurement data 310 may comprise a categorical variable and a respective categorical variable value may be associated with one respective value bin. Alternatively or in addition, the measurement data may comprise a discrete variable, and the discrete variable may comprise M different values, and the values of the discrete variable are quantized to at most M value bins.

Optionally, the measurement data 210 may comprise a number of data sets of DUT tests; and the number of value bins of the measurement data may be determined using the number of data sets and using a partitioning based on a number of categorical variables value combinations, and/or using the number of data sets and using a partitioning based on the parameter a, and/or using the number of data sets and using a partitioning based on a number of continuous and discrete variables, and/or using the number of data sets using a partitioning based on a number of continuous variables.

For example, based on the optionally binned measurement data, an information about a conditional distribution of measurement results corresponding to a first subset of measurement conditions (block 220) and an information about at least one sample distribution, wherein the at least one sample distribution is comparable with the conditional distribution (block 230), may be determined.

As another optional feature, corresponding to the example of FIG. 2, determining the information about the at least one sample distribution may comprise determining an information about a plurality of empirical distributions.

Using the information about the conditional distribution and using the information about the at least one sample distribution, a statistically significant dissimilarity value may be determined (block 250), as an example, based on a determination of a plurality of dissimilarity measures (block 240).

Hence, the information about the characteristics of the one or more DUTs may comprise the statistically significant dissimilarity value or may be based on the statistically significant dissimilarity value.

Furthermore, optionally, as shown, the method may comprise a selection of a dissimilarity measure, e.g. Dₛ, of the plurality of dissimilarity measures. The selected dissimilarity measure, e.g. Dₛ may comprise a smallest deviation to the statistically significant dissimilarity value e.g. d(v). This is shown by block 320.

Optionally, the information about the characteristics of the one or more DUTs may comprise an information about the selected dissimilarity measure. Hence, the selected dissimilarity measure, e.g. Dₛ, may provide an information or may allow to evaluate an information about the one or more DUTs.

Furthermore, optionally, a mean value of an empirical distribution corresponding to the selected dissimilarity measure (e.g. having an index s′), e.g. Dₛ, may be determined (block 330) and optionally a mean value, e.g. pᵥ, of the conditional distribution of the measurement results corresponding to the first subset of measurement conditions (block 340) may be determined.

In addition, as optionally shown, a mean-aligned dissimilarity measure, e.g. Dₛ' may be determined (block 350) for example using the mean value e.g. qₛ' and for example using the mean value, e.g. pᵥ.

Based on the selected dissimilarity measure, e.g. D_{s′} and the mean-aligned dissimilarity measure, e.g. D_{S′} an information about a normalized dissimilarity fraction, e.g.

$${μ}^{′} = \frac{{D}_{{S}^{′}} - {\overline{D}}_{{S}^{′}}}{{D}_{{S}^{′}}} ,$$

may be determined. μ′ may allow to characterize the one or more DUTs. μ′ may allow to evaluate which fraction of the divergence can, for example, be attributed to differing means (block 360).

The information about the characteristics of the one or more DUTs may hence comprise the information about the normalized dissimilarity fraction, e.g. μ′.

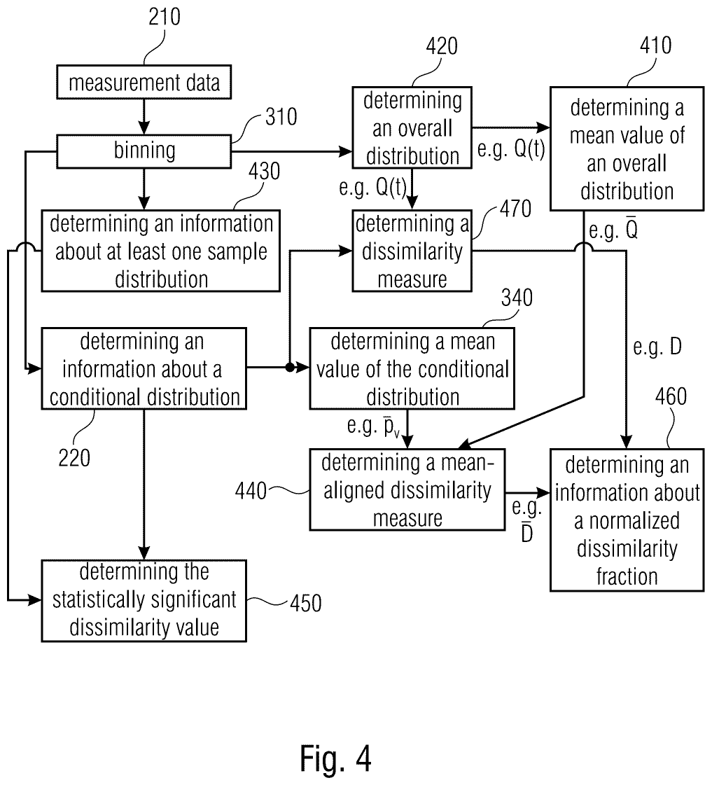

FIG. 4 shows a schematic block diagram of another method with optional features according to embodiments of the invention.

As explained in the context of FIG. 1 an inventive method may comprise a determination 220, 430 of an information about at least one sample distribution and about a conditional distribution. Furthermore the method may comprise determining (block 450) the statistically significant dissimilarity value, e.g. d(v), using the information about the conditional distribution and using the information about the at least one sample distribution.

As optionally shown in FIG. 4, the method may comprise a determination (block 340) of a mean value e.g. pᵥ of the conditional distribution of the measurement results corresponding to the first subset of measurement conditions. Furthermore, as another optional feature, the method may comprise a determination of a mean value, e.g. Q, of an overall distribution of the measurement results (block 410). Therefore, the method may optionally comprise a determination of an overall distribution, e.g. Q(t) of the measurement results of all test cases (block 420).

Furthermore, the method may optionally comprise, as shown, a determination of a mean-aligned dissimilarity measure, e.g. D, using the mean value, e.g. pᵥ of the conditional distribution of the measurement results corresponding to the first subset of measurement conditions and for example using the mean value, e.g. Q, of the overall distribution of the measurement results (block 440).

In addition, the method may optionally comprise determining a dissimilarity measure, e.g. D, between the conditional distribution and the overall distribution (470).

Furthermore, optionally, the method may comprise determining an information about a normalized dissimilarity fraction, e.g.

$$μ = \frac{D - \overline{D}}{D} ,$$

using the mean-aligned dissimilarity measure, e.g. D, and using the dissimilarity measure, e.g. D, between the conditional distribution and the overall distribution (block 460).

The information about the characteristics of the one or more DUTs may hence comprise the information about the normalized dissimilarity fraction, e.g. μ.

Optionally (not shown) the measurement data comprises a number of data sets of DUT tests and the number of value bins of the measurement data is determined using the number of data sets and using a partitioning based on a number of categorical variables value combinations, and/or using the number of data sets and using a partitioning based on the parameter a, and/or using the number of data sets and using a partitioning based on a number of continuous and discrete variables, and/or using the number of data sets using a partitioning based on a number of continuous variables.

Optionally, the measurement data may comprise the measurement results and values of one or more corresponding independent variables and the method may further comprise determining the first subset of measurement conditions, such that measurement conditions of the first subset are neighbored.

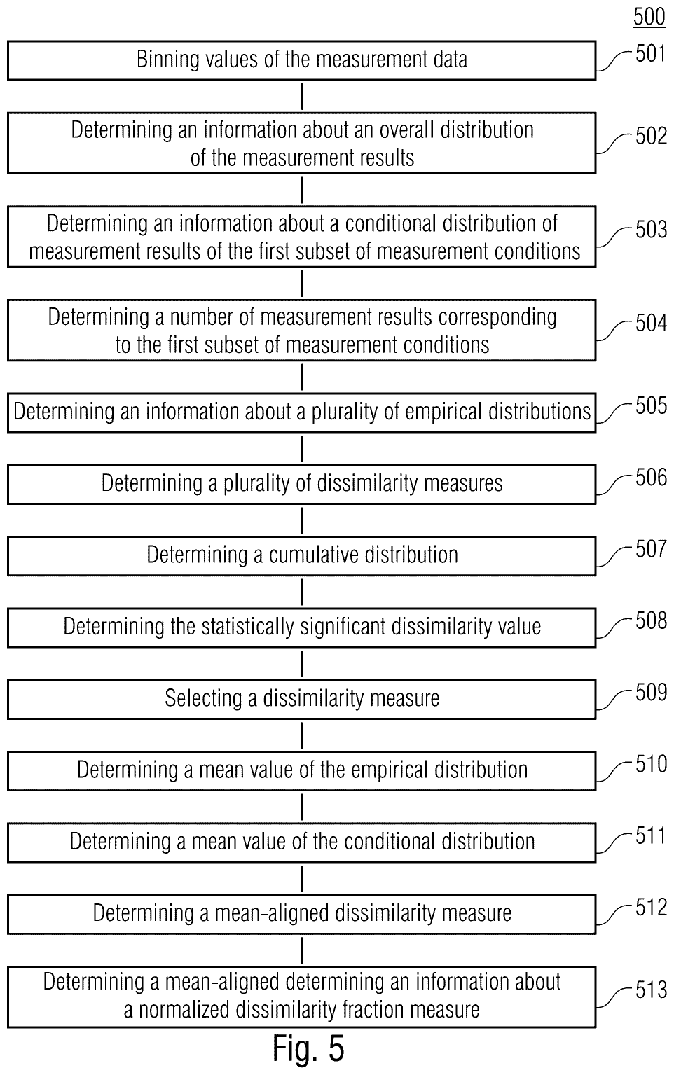

FIG. 5 shows a block diagram of a further method according to embodiments of the invention. Method 500 comprises binning 501 values of the measurement data, wherein measurement results and/or independent variable values of the measurement data are quantized, e.g. binned, to value bins.

Method 500 further comprises determining 502 an information, e.g. a probability; e.g. Q(t), about an overall distribution of the measurement results based on measurement results of respective, e.g. of all, value bins.

Furthermore, method 500 comprises determining 503 an information about a conditional distribution of measurement results of the first subset of measurement conditions, wherein the first subset of measurement conditions is associated with the independent variable values of a respective value bin and determining 504 a number, e.g. n(v), of measurement results corresponding to the first subset of measurement conditions.

Moreover method 500 comprises determining 505 an information about a plurality of empirical distributions, e.g. qₛ, of measurement results of a plurality of subsets of the measurement data, wherein a number of measurement results considered for the determination of the information about a respective empirical distribution is equal to the number, e.g. n(v), of measurement results of, e.g. corresponding to, e.g. associated to, the first subset of measurement conditions, and wherein the measurement results of a respective subset of the measurement data are a set of randomly or pseudo randomly selected measurement results of the measurement data.

In addition, method 500 comprises determining 506 a plurality of dissimilarity measures, e.g. Kullback-Leibler divergences, between the conditional distribution and respective, e.g. each of the, empirical distributions using the information about the conditional distribution, e.g. the conditional distribution itself, and using the information about the respective empirical distribution.

Method 500 further comprises determining 507 a cumulative distribution, e.g. CDF, of the plurality of dissimilarity measures and determining 508 the statistically significant dissimilarity value, e.g. d(v), such that only a predetermined portion of the empirical distributions comprises a dissimilarity measure with respect to the conditional distribution, which is smaller than or equal to the statistically significant dissimilarity value.

Furthermore, method 500 comprises selecting 509 a dissimilarity measure, e.g. Dₛ, of the plurality of dissimilarity measures, wherein the selected dissimilarity measure comprises a smallest deviation to the statistically significant dissimilarity value, e.g. d(v), out of dissimilarity measures of the plurality of dissimilarity measures and determining 510 a mean value of the empirical distribution corresponding to the selected dissimilarity measure.

Furthermore, method 500 comprises determining 511 a mean value, e.g. pᵥ, of the conditional distribution of the measurement results corresponding to the first subset of measurement conditions and determining 512 a mean-aligned dissimilarity measure between the conditional distribution and the empirical distribution corresponding to the selected dissimilarity measure.

Moreover method 500 comprises determining 513 an information about a normalized dissimilarity fraction, e.g.

$${μ}^{′} = \frac{{D}_{{S}^{′}} - {\overline{D}}_{{S}^{′}}}{{D}_{{S}^{′}}} ,$$

using the mean-aligned dissimilarity measure, e.g. Dₛ′, and using the dissimilarity measure, e.g. Dₛ, between the conditional distribution and the empirical distribution corresponding to the selected dissimilarity measure, wherein the information about the characteristics of the DUTs comprises the information about the normalized dissimilarity fraction.

Although any of the steps as explained in the context of FIG. 5 are to be seen as optional it is to be noted that in particular steps 509 to 512 may not be performed, e.g. skipped, according to embodiments. Hence, the information about the characteristics of the DUTs may comprise the selected dissimilarity measure.

Referring to all of the before mentioned methods, optionally, a plurality of statistically significant dissimilarity values, e.g. d(v), and/or a plurality of normalized dissimilarity fractions, e.g. μ′; e.g. μ, may be determined for different subsets of measurement conditions corresponding to respective value bins.

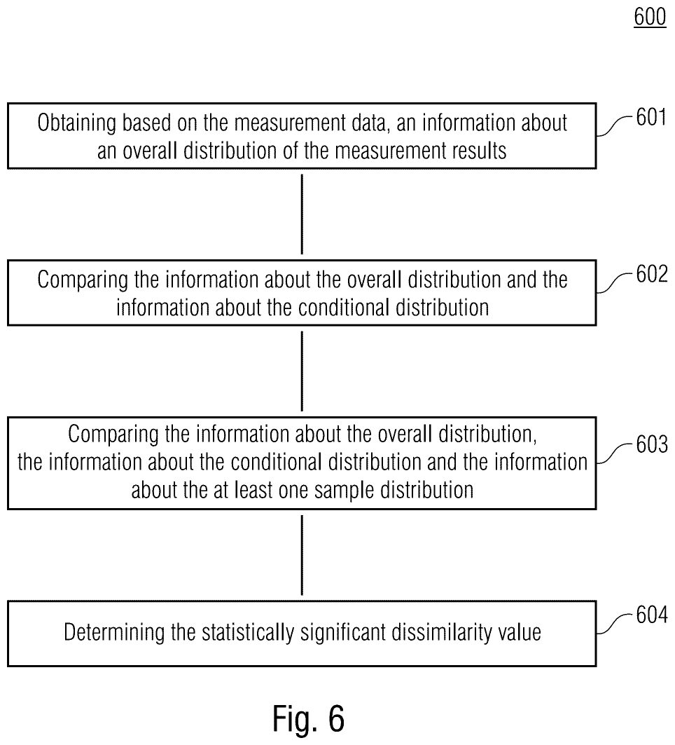

FIG. 6 shows a block diagram of a method comprising comparison steps according to embodiments of the invention. FIG. 6 shows method 600, the method comprising obtaining 601 based on the measurement data, an information about an overall distribution of the measurement results and comparing 602 the information about the overall distribution and the information about the conditional distribution, wherein the information about the at least one sample distribution is determined based on the comparison of the information about the overall distribution and the information about the conditional distribution.

Furthermore, the method comprises comparing 603 the information about the overall distribution, the information about the conditional distribution and the information about the at least one sample distribution and determining 604 the statistically significant dissimilarity value based on the comparison of the information about the overall distribution, the information about the conditional distribution and the information about the at least one sample distribution.

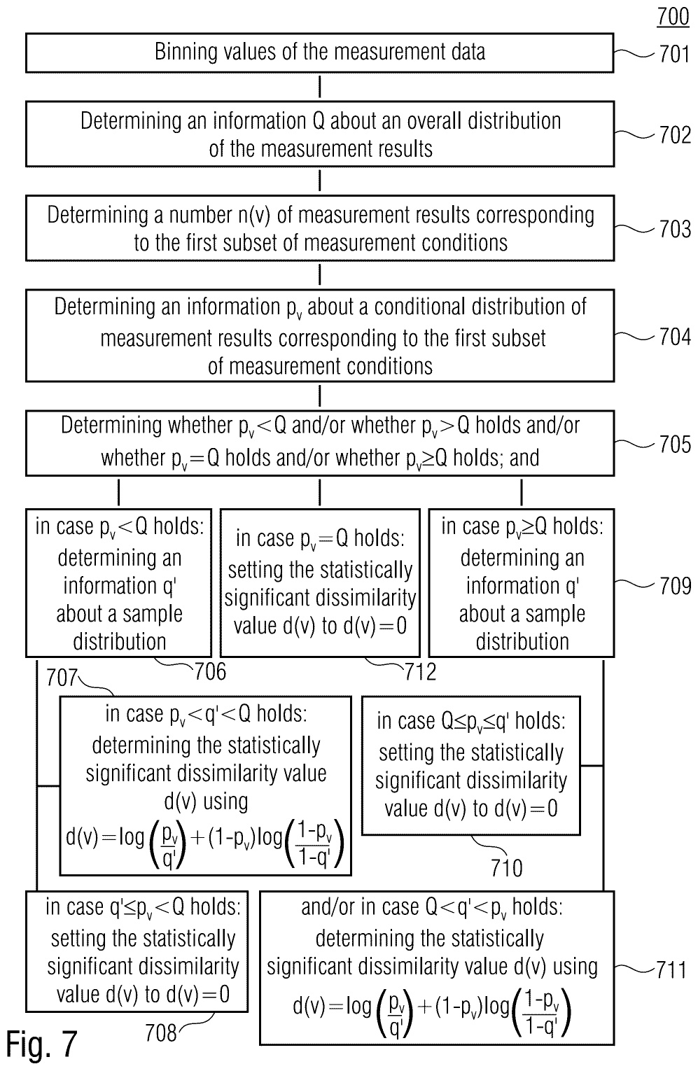

FIG. 7 shows a block diagram of a further method comprising comparison steps according to embodiments of the invention. FIG. 7 shows method 700, wherein the method comprises binning 701 values of the measurement data, wherein measurement results and/or independent variable values of the measurement data are binned to value bins; and wherein the measurement results are Boolean target variables having measurement results of true or false.

The method 700 further comprises determining 702 an information Q about an overall distribution of the measurement results, wherein information Q is a probability for a measurement result to be true, or a probability for a measurement result to be false, based on the overall measurement results of the measurement data and determining 703 a number n(v) of measurement results corresponding to the first subset of measurement conditions, wherein the first subset of measurement conditions is associated with the independent variable values of a respective value bin.

Furthermore, method 700 comprises determining 704 an information pᵥ about a conditional distribution of measurement results corresponding to the first subset of measurement conditions, wherein the information pᵥ is a probability for a measurement result to be true based on the measurement results corresponding to the first subset of measurement conditions, or wherein the information pᵥ is a probability for a measurement result to be false based on the measurement results corresponding to the first subset of measurement conditions.

In addition, method 700 comprises determining 705 whether pᵥ<Q and/or whether pᵥ>Q holds and/or whether pᵥ=Q holds and/or whether pᵥ≥Q holds.

In case pᵥ<Q holds,, the method comprises determining 706 an information q′ about a sample distribution, using q′=k′/n(v), wherein k′ is a largest number of true test cases fulfilling Pr (X≤k′)≤1-C, wherein C is a confidence value, with Pr (X≤k′)≤1-C being the condition that the probability, Pr, of having less than or equal to k′ positive measurement results X when choosing n(v) arbitrary measurement results from the measurement data is equal or less than confidence C subtracted from 1.

Furthermore, in case pᵥ<q′<Q holds, the method comprises determining 707 the statistically significant dissimilarity value d(v) using

$$d ( v ) = log ( \frac{{p}_{v}}{{q}^{′}} ) + ( 1 - {p}_{v} ) log ( \frac{1 - {p}_{v}}{1 - {q}^{′}} ) .$$

Alternatively or in addition, in case q′<p><Q holds, the method comprises setting 708 the statistically significant dissimilarity value d(v) to d(v)=0.

Alternatively or in addition, in case pᵥ>Q holds, the method comprises determining 709 an information q′ about a sample distribution, using q′=k′/n(v) according to the smallest k′ fulfilling Pr (X≤k′)≤C, with Pr (X≤k′)≤C being the condition that the probability, Pr, of having less than or equal to k′ positive measurement results X when choosing n(v) arbitrary measurement results from the measurement data is equal or less than the confidence C.

Furthermore, in case Q≤pᵥ≤q′ holds, the method comprises setting 710 the statistically significant dissimilarity value d(v) to d(v)=0, or in case Q<q′<pᵥ holds, the method comprises determining 711 the statistically significant dissimilarity value d(v) using

$$d ( v ) = log ( \frac{{p}_{v}}{{q}^{′}} ) + ( 1 - {p}_{v} ) log ( \frac{1 - {p}_{v}}{1 - {q}^{′}} ) .$$

Alternatively or in addition, in case pᵥ=Q holds, the method comprises setting 712 the statistically significant dissimilarity value d(v) to d(v)=0.

It is to be noted that method 700 may optionally comprise determining a plurality of respective statistically significant dissimilarity values for different subsets of measurement conditions corresponding to respective value bins.

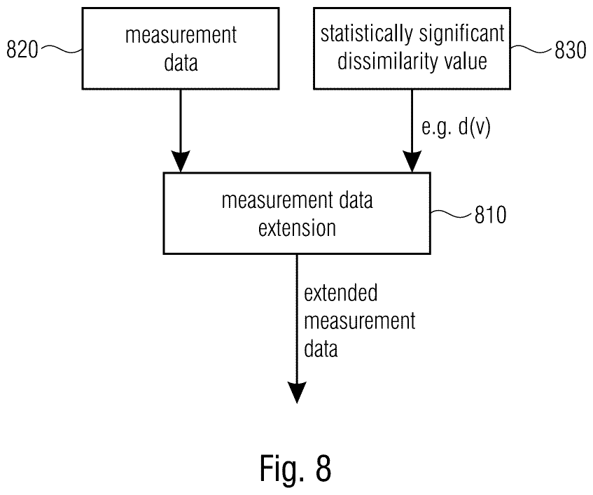

FIG. 8 shows a schematic block diagram for an extension of measurement data according to embodiments of the invention. As shown in FIG. 8 methods according to embodiments may comprise an extension of measurement data, 810, based on or using the measurement data 820 and the statistically significant dissimilarity value 830, e.g. d(v).

The extended measurement data may be a combination of the measurement data 820 itself and associated measurement data meta information, wherein the associated measurement data meta information is determined based on the statistically significant dissimilarity value 930. Furthermore, the measurement data meta information may comprise an information about statistically significant dissimilarities between measurement results corresponding to the first subset of measurement conditions and overall measurement results or between measurement results corresponding to the first subset of measurement conditions and measurement results of a selected sample distribution. A determination of the measurement data meta information may be performed in block 810.

Furthermore, it is to be noted that optionally, for determining the normalized dissimilarity fraction, e.g. μ, or μ′, a mean-aligned dissimilarity measure; and a dissimilarity measure between the conditional distribution and an overall distribution of the measurement results, wherein the normalized dissimilarity fraction comprises an information about an amount of the dissimilarity measure that is associated with differing means between the conditional distribution and the overall distribution may be used,

Alternatively, for determining the normalized dissimilarity fraction, e.g. μ, or μ′, a dissimilarity measure between the conditional distribution and a sample distribution, e.g. an empirical distribution, of the measurement results, wherein the normalized dissimilarity fraction comprises an information about an amount of the dissimilarity measure that is associated with differing means between the conditional distribution and the sample distribution may be used. Furthermore, the measurement data meta information may comprise an information about the normalized dissimilarity fraction

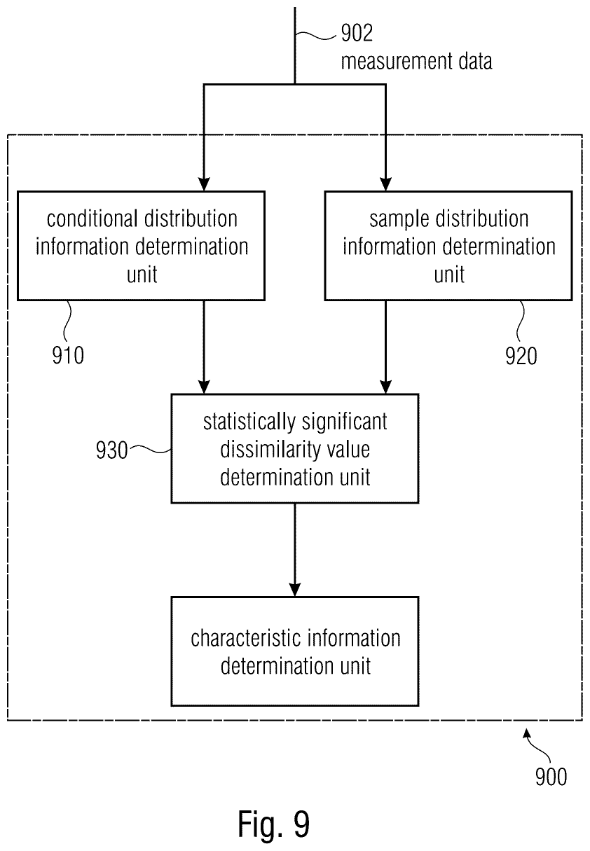

FIG. 9 shows a schematic view on an apparatus according to embodiments of the invention. FIG. 9 shows apparatus 900 for determining an information about characteristics of one or more devices under test (DUTs)

Apparatus 900 may optionally be configured to receive measurement data 902 from an automated test equipment (ATE), the measurement data comprising a plurality of measurement results and information describing corresponding measurement conditions of the devices under test (DUTs).

Furthermore, the apparatus comprises a conditional distribution information determination unit 910, configured to determine an information about a conditional distribution of measurement results corresponding to a first subset of measurement conditions and a sample distribution information determination unit 920, configured to determine an information about at least one sample distribution, wherein the at least one sample distribution is comparable with the conditional distribution

Moreover, apparatus 900 comprises a statistically significant dissimilarity value determination unit 930, configured to determine a statistically significant dissimilarity value using the information about the conditional distribution and using the information about the at least one sample distribution; wherein the information about the characteristics of the one or more DUTs comprises the statistically significant dissimilarity value or is based on the statistically significant dissimilarity value. Therefore, as optionally shown, apparatus 900 may comprise a characteristic information determination unit 940.

In the following further embodiments according to the invention are disclosed. It is to be noted that any of the features, functionalities and details thereof may be used with any of the embodiments explained before, individually or taken in combination. Furthermore embodiments according to the invention may be explained in different words.

In general, embodiments according to the invention may comprise plots with information highlight or may allow a provision thereof. The following sections may hence for example, be titled “Plots with Information Highlight”.

The following may provide an overview over some embodiments of the invention:

Plots shall often convey how device properties depend on operating conditions. Conventional plots suffer from several challenges for this task, namely, for example, (1) obfuscation, (2) statistical fluctuations can pretend non-existent dependencies, (3) visual bias due to nonuniform distribution of test cases, and (4) difficulty to estimate fractions or distributions visually.

Embodiments according to the invention comprise or propose highlighting regions of independent variables where the target distribution differs e.g. in a statistically significant way, for example, from the overall target distribution. Two highlighting approaches, according to embodiments, will be disclosed or proposed that can, for example, be applied to e.g. all common plot types. Computation of the highlight parameters will be explained.

Section 1: In the following a motivation of embodiments according to the invention may be presented:

In post-silicon validation, plots may, for example, be used often in an attempt to gain an understanding how a target variable depends on the independent variables, e.g. without being misguided by statistical fluctuations.

As an example, when the target variable is a Boolean error variable, we may, for example, want to know how the error probability depends on the independent variables. Note that error probabilities can, for example, be very low, such as 1% or even 0.1%. As an example, when the target variable is a continuous performance variable, we may, for example, want to know how the distribution of the target variables depends on the independent variables, e.g. not only in terms of its mean but, for example, also in terms of distribution shape. Independent variables can e.g., be continuous supply voltages, or discrete numeric register settings or categorical device modes.

Conventional plots may, for example, face several challenges towards this task (It is to be noted that any of the following challenges may be addressed with embodiments of the invention): Obfuscation; Statistical fluctuations can look like non-existing dependencies; Unequal distributions of test cases can lead to visual bias; Visual estimation of fractions or distributions can be difficult.

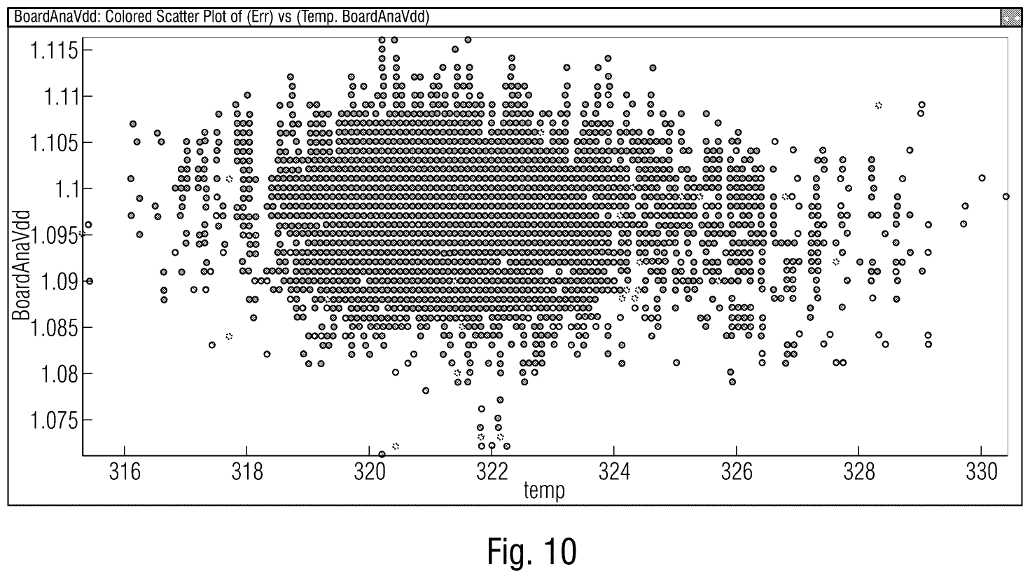

For following explanations reference is made to FIG. 10. FIG. 10 shows an example for a scatter plot with Boolean target variable (true: error, blue: no error). Seldom errors may be difficult to see.

We will now explain these challenges for several common plot types (It is to be noted that any of the following plot types may be addressed or used with embodiments of the invention):

Scatter plot with Boolean target as color. Let us assume red dots for error cases, like in FIG. 10. FIG. 10 shows a plot of test cases for voltages over temperatures. Obfuscation: Large numbers of good test cases may, for example, hide seldom error cases. When problems are seldom, it may, for example, be difficult to judge visually, whether a clustering of a few error cases is statistically significant or a mere artifact of statistical fluctuations. When test cases are non-uniformly distributed, it may, for example, be difficult to judge visually whether a (x, y)-region appears more red because it has a higher fraction of error cases or because there are simply more test cases in this region. It may, for example, be difficult to estimate and compare error fractions across (x, y).

Scatter plot with continuous target on y-axis: When test cases are non-uniformly distributed along x, it may, for example, be difficult to judge visually whether a wider spread of y-values in some x-region is due to higher variance or is merely due to more test cases in this x-region. It may, for example, be difficult to judge visually which value differences are due to statistical outliers and which differences are due to statistically significant deviations. Target distributions may, for example, be difficult to estimate and compare across x. When test cases are dense, obfuscation may, for example, make this estimate difficult. When test cases are sparse, statistical fluctuations may, for example, make this estimate also difficult.

Scatter plot with continuous target as color and independent variables along x and y. Seldom outliers may, for example, be hidden by many good test cases. When test cases are non-uniformly distributed along (x, y), it may, for example, be difficult to judge visually whether a wider spread of color values is due to higher variance or is merely due to more test cases. It may, for example, be difficult to judge visually which color differences are due to statistical outliers or due to statistically significant deviations. Distributions of color values may, for example, be e.g. extremely difficult to grasp, let alone comparing them across (x, y). Even the average target value (color) may, for example, be difficult to estimate visually.

Stacked bars with stacks for error/non-error, one bars per value of an independent variable. It may, for example, be difficult to compare error fractions across varying bar heights. On the other side, full bars that may, for example, be normalized to equal heights may, for example, not convey the number of test cases and thus may, for example, not indicate how reliable a fraction is estimated. It may, for example, be difficult to judge whether differing error fractions can be explained by statistical fluctuations or may be or even must be assumed to represent statistically significant deviations.

Stacked distributions may, for example, have the same challenges as stacked bars.

Box plots may, for example, make comparison of means and quantiles easy but may, for example, hide distribution details.

Section 2: In the following goals according to embodiments are disclosed. In other words, embodiments according to the invention may fulfill some or even all of the following characteristics.

One high-level goal according to embodiments may, for example, be to help users understand better how the target distribution depends—e.g. in a statistically significant way-on independent variables. We, or for example according to embodiments one, can, for example, assume that the overall target distribution may already be known. Regions of the independent variables that follow this overall target distribution may, for example, not be of interest. We want to direct user attention, or as an example according to embodiments user attention is directed, e.g. using a highlighting, to regions, where the local target distribution differs—e.g. in a statistically significant way—e.g. from the overall target distribution, or for example from a sample distribution. The local target distribution can, for example, have a different mean than the overall distribution or can have the same mean but a different variance. Both differences or mixtures thereof may, for example, be of interest.

Requirements when directing user attention may, for example, be:
Suppress statistical fluctuations, show only statistically significant deviations from the overall target distribution. I.e., for example, reflect uncertainty due to few local test cases (optional); Independence of the test case distribution along independent variables. I.e., for example, use conditional distributions (optional); Detect differing target distribution, e.g. even when the mean is unchanged (optional); Avoid masking effects that hide information (optional); Highlighting scheme may, for example, support many or as an example even all plot types (optional); Highlighting scheme is consistent across plot types (optional); Highlighting scheme is compatible with brushing (optional).

Some or even all, or any combination of these requirements may be addressed or even fulfilled using embodiments of the invention.

Section 3: In the following an optional nomenclature for a better understanding of embodiments according to the invention is disclosed.

The target variable may, for example, be denoted T, e.g. with values 1. Independent variables may, for example, be jointly denoted V, e.g. with joint values v. Probability distributions that may, for example, be estimated from a large enough number of test cases so that they may, for example, approximate the e.g. true distributions well will may, for example, be denoted by upper case letters, e.g., P(t) or Q(t), while empirical distributions e.g. based on potentially few test cases may, for example, be denoted by lower case letters, e.g., p(t), q (t). Value sets may, for example, be denoted by script upper case letters, e.g., [symbol] , [symbol] . Pr (T=1) may, for example, stand for the probability that random variable T takes value t, while Pr (T=t|X=x) may, for example, stand for the conditional probability that random variable T takes value t, e.g. under the assumption that random variable X takes value x.

Section 4: In the following, concepts according to embodiments of the invention are disclosed.

In the following further features, functionalities and aspects according to embodiments of the invention are explained. It is to be noted that all features, functionalities and aspects may be used alone or in combination with any other feature, functionality and/or aspect of other embodiments, alone or in combination.

Consider a plot of N test cases that may, for example, visualize target variable T, e.g. as a function of one or multiple independent variables, e.g. jointly represented by v. E.g. to avoid confusion with plot axes, we may avoid calling these variables y and x. In the following, we assume, or for example according to embodiments one can assume, discrete variables with discrete values t∈ [symbol] , v∈ [symbol] , where n(v) test cases may, for example, take value V′=v. Support for continuous variables, e.g. explanations of features, functionalities and aspects of embodiments addressing continuous variables will be, e.g. additionally, covered in sections 6.1 and 6.2.

The proposal will be, or for example, the idea according to embodiments of the invention may, for example, be, to highlight values v∈ [symbol] of independent variables e.g. based on the statistically significant dissimilarity d(v) between the empirical local distribution of target variable t e.g. at location v,

$${p}_{v} ( t ) = p ( t \vert v ) = Pr ( T = t \vert V = v ) , \qquad ( 1 )$$

and, for example, the overall target distribution

$$Q ( t ) = Pr ( T = t ) . \qquad ( 2 )$$

The highlight intensity h (v) at location v∈ [symbol] may, for example, thus be a function of the dissimilarity

$$h ( v ) = f ( d ( v ) ) . \qquad ( 3 )$$

Section 4.1: In the following section, the optional usage of the Kullback-Leibler divergence, according to concepts of embodiments, is disclosed.

The Kullback-Leibler divergence D_{KL}(P(t)∥Q(t)) [Cover-2006, section 2.3] may, for example, be the most commonly used dissimilarity measure between two probability distributions P(t) and Q(t). As an example, for discrete distributions it may, for example, be given by

$${D}_{KL} ( P ( t ) ‖ Q ( t ) ) = P ( t ) log \frac{P ( t )}{Q ( t )} . \qquad ( 4 )$$

The Kullback-Leibler divergence is non-negative, D_{KL}≥0, and, in the discrete case, is zero if and only if the two distributions are equal.

The t∈ [symbol] may, for example, sum only over non-empty bins of distribution Q(t) and P(t) may, for example, be, or even must be zero where Q(t) is zero. Note, the Kullback-Leibler divergence is not symmetric with respect to exchange of Q(t) and P(t) and does not satisfy the triangle inequality. Therefore, it may, for example, not qualify as a distance metric, which may, for example, not be required here.

We will use the Kullback-Leibler divergence, or for example according to embodiments the Kullback-Leibler divergence may, for example, be used to compare the local empirical target distribution p(t|v), e.g. at location v, for example, with the overall target distribution Q(t). The resulting divergence D (v) at location v may, for example, be:

$$\begin{matrix}D ( v ) = {D}_{KL} ( p ( t \vert v ) ‖ Q ( t ) ) \\ = p ( t \vert v ) log \frac{p ( t \vert v )}{Q ( t )}\end{matrix} \qquad ( 5 )$$

Since the local empirical target distribution p(t|v) may, for example, be a conditional distribution that may, for example, restricts the overall target distribution Q(t), p(t|v) may, for example, be zero where Q(t) is zero, which may, for example, satisfy the above mentioned requirement.

Section 4.2: In the following section, an example for the relation to mutual information, according to concepts of embodiments, is disclosed.

For a plot (T, V), the mutual information I (T, V′) [Cover-2006, section 2.3] may, for example, quantify the amount of information in independent variables v, e.g. about target variable T. For discrete variables, it may, for example, be computed as:

$$I ( T ; V ) = {P}_{TV} ( t , v ) log \frac{{P}_{TV} ( t , v )}{{P}_{T} ( t ) {P}_{V} ( v )} \qquad ( 6 )$$

As an example, now we use the well-known equation for the conditional probability

$${P}_{TV} ( t , v ) = {P}_{T \vert V} ( t \vert v ) {P}_{V} ( v ) , \qquad ( 7 )$$

where P_{TV}(t, v) may, for example, be the joint distribution for T=t and V=v, PT\V(t|v) may, for example, be the conditional probability that T=t given V=v, and P_{V}(v) may, for example, be the marginal probability for V=v. With this we may, for example, obtain:

$$\begin{matrix}I ( T ; V ) = {P}_{T \vert V} ( t \vert v ) {P}_{V} ( v ) log \frac{{P}_{T \vert V} ( t \vert v ) {P}_{V} ( v )}{{P}_{T} ( t ) {P}_{V} ( v )} \\ = {P}_{T \vert V} ( t \vert v ) {P}_{V} ( v ) log \frac{{P}_{T \vert V} ( t \vert v )}{{P}_{T} ( t )} \\ = {P}_{V} ( v ) {P}_{T \vert V} ( t \vert v ) log \frac{{P}_{T \vert V} ( t \vert v )}{{P}_{T} ( t )} \\ = {P}_{V} ( v ) {D}_{KL} ( {P}_{T \vert V} ( t \vert v ) ‖ {P}_{T} ( t ) )\end{matrix} \qquad ( 8 )$$

As an example, we find that mutual information may, for example, be a weighted sum of Kullback-Leibler divergences, e.g. between the conditional target distribution Pry (t|v) that we had called, as an example, the local target distribution p(t|v) and the overall target distribution Pr (t) that we had denoted, as an example, Q(t). For an empirical estimate, weights

$${P}_{V} ( v ) = \frac{n ( v )}{N} \qquad ( 9 )$$

may, for example, represent the test case distribution, e.g. along independent variables. We can, for example, see that the divergences may exclude factor P_{V}(v) and may, for example, thus be independent of the test case distribution P_{V}(v), e.g. along independent variables, e.g. as desired.

Also, the divergence may, for example, be the normalized local contribution to the total information, e.g. in all independent variables about the target variable.

Section 4.3: In the following section, an example for statistically significant divergence, according to concepts of embodiments, is disclosed.

The overall target distribution Q(t) may, for example, be computed from all test cases and can, for example, thus be treated as accurately estimated distribution, without statistical fluctuations.

However, the local conditional target distribution p(t|v) may, for example, be estimated optionally only from the subset of those test cases where the independent variables take value V=v. As an example, let n(v) be the number of such test cases. As an example, since N (v) can, for example, be rather small, p(t|v) can, for example, be subject to substantial statistical fluctuations.

It may, for example, seem most natural to ask how close the fluctuating empirical local distribution p(t|v) can come to the overall target distribution Q(t), and treat the remaining divergence as the desired statistically significant divergence. Unfortunately, this may, for example, not be possible, e.g. since the statistics of p(t|v) and thus its variance may, for example, be unknown.

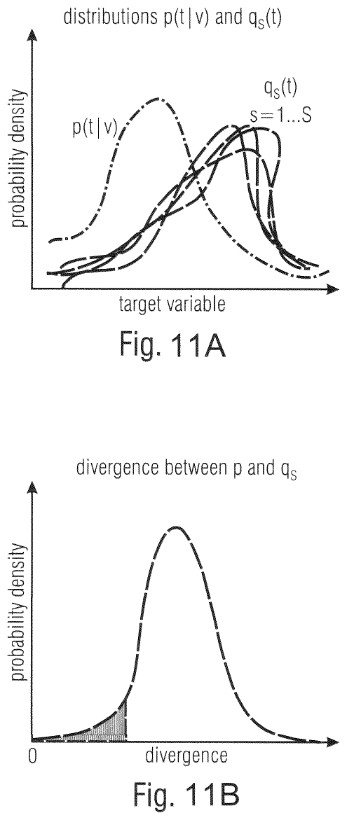

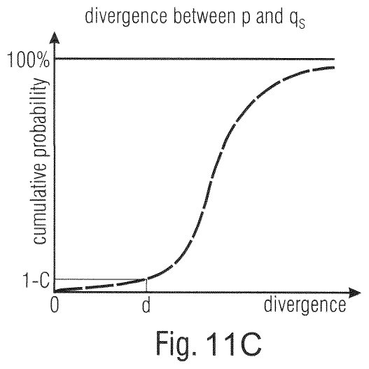

Instead, the e.g. usual approach in statistics may, for example, be to phrase a null hypothesis, e.g. about a known distribution, for example in this case about Q(t). As null hypothesis we may, for example, assume that the local distribution p(t|v) can, for example, be explained as random fluctuation when drawing a sample of n(v) test cases from the e.g. known overall distribution Q(t). As an example, let qₛ(t) be the empirical target distribution of such a random sample s of n(v) test cases that may, for example, be randomly selected from the known overall distribution Q(t). As an example, we may take a large number S′ of such samples s=1 . . . . S′ consisting of n(v) test cases each and thus get S′ empirical distributions, qₛ(1), s=1 . . . . S, see FIG. 11a).

FIG. 11 shows an example fora statistically significant divergence according to embodiments of the invention: a) Empirical target distributions qₛ(1), s=1 . . . . S′ from random samples of the overall target distribution, compared to the local target distribution p(t|v). b) Probability density distribution of divergences Dₛ(v) between qₛ(1) from random samples and the local target distribution p(t|v). c) The statistically significant divergence d marks the lower 1-C percentile of the cumulative distribution of Dₛ(v), where C is the confidence level, e.g., C=95%.

For each empirical distribution qₛ(t), we may, for example, compute its divergence Dₛ(v) e.g. from the empirical local distribution p(t|v), e.g. at location v

$$\begin{matrix}{D}_{s} ( v ) = {D}_{KL} ( p ( t \vert v ) ‖ {q}_{s} ( t ) ) \\ = p ( t \vert v ) log \frac{p ( t \vert v )}{{q}_{s} ( t )}\end{matrix} \qquad ( 10 )$$

for example, so that we can investigate how divergences Dₛ(v), s=1 . . . . S may vary. FIG. 11b) shows an example of the probability density distribution FIG. 11c) shows an example of and the cumulative probability distribution of Dₛ (v), e.g. at a given location v.

As an example, For confidence level, e.g., C=95%, the statistically significant divergence d(v) may, for example, be the divergence value where fraction 1-C of all divergences may, for example, be smaller, i.e. optionally, it marks the lower 1-C percentile.

$$d ( v ) : Pr ( {D}_{s} ( v ) < d ( v ) ) = 1 - C \qquad ( 11 )$$

Section 4.4: In the following section, an optional usage of a mean-aligned divergence for continuous target variable, according to concepts of embodiments, is disclosed.

When we are interested in which fraction of the divergence D=D_{KL}(P(t)|Q(t)) can, for example, be attributed to differing means, e.g. P and Q of distributions P(t) and Q(t), we may, for example, define the mean-aligned divergence as

$$\overline{D} = {D}_{KL} ( P ( t ) - \overline{P} ‖ Q ( t ) - \overline{Q} ) . \qquad ( 12 )$$

In our case, when comparing the local distribution pᵥ (t) with the overall distribution Q(t) this may, for example, become

$$\overline{D} = {D}_{KL} ( {p}_{v} ( t ) - {\overline{p}}_{v} ‖ Q ( t ) - \overline{Q} ) . \qquad ( 13 )$$

Comparing the two means, may, for example, tell us whether local mean is higher than the overall mean, p̅ᵥ>Q̅, or lower, p̅ᵥ<Q̅. The fraction of divergence that can, for example, be explained by differing means may, for example, be thus

$$μ = \frac{D - \overline{D}}{D} . \qquad ( 14 )$$

Section 4.5: In the following section, an example for Boolean target variables, according to concepts of embodiments, is disclosed.

Boolean target variables may, for example, follow a binomial distribution, optionally with the fraction of true target values as only parameter. We may, for example, call this fraction Q for the overall distribution and pᵥ for the local distribution at location V=v. As an example, since the target variable takes only two values, true with probability Q or pᵥ, and false with probability 1-Q or 1-pᵥ, the expression(5) for divergence I) (v) may, for example, become

$$D ( v ) = {p}_{v} log \frac{{p}_{v}}{Q} + ( 1 - {p}_{v} ) log \frac{1 - {p}_{v}}{1 - Q} . \qquad ( 15 )$$

Knowing that target values follow a binomial distribution with known probability Q, we can, for example, compute the distribution of empirical probabilities q e.g. analytically e.g. without actually drawing random samples of n(v) test cases as outlined in section 4.3 as an example.

The probability of drawing exactly k test cases with true target value out of n(v) randomly selected test cases may, for example, be given by the binomial probability mass

$$Pr ( X = k ) = {{Q}^{k} ( 1 - Q )}^{n ( v ) - k} . \qquad ( 16 )$$

The probability of drawing up to k′ such test cases may, for example, be given by the cumulative binomial distribution.

$$Pr ( X \leq {k}^{′} ) = {\sum }_{k = 0}^{{k}^{′}} ( \begin{matrix}n ( v ) \\ k\end{matrix} ) {{Q}^{k} ( 1 - Q )}^{n ( v ) - k} . \qquad ( 17 )$$

The inverse cumulative distribution may, for example, find k′ for a given probability. The corresponding empirical probability may, for example, be simply q′=k′/n(v) which may lead to the following divergence from the local empirical distribution pᵥ.

$$D ( v ) = {p}_{v} log \frac{{p}_{v}}{{q}^{′}} + ( 1 - {p}_{v} ) log \frac{1 - {p}_{v}}{1 - {q}^{′}} \qquad ( 18 )$$

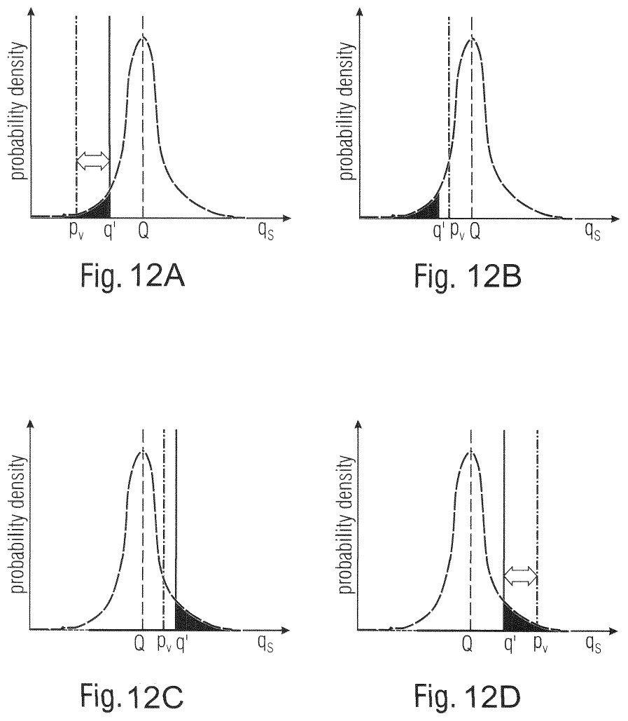

As an example, for both pᵥ<q′ and q′<pᵥ, the divergence I) may, for example, fall monotonously as q′ moves away from pᵥ. Therefore, q′ and D(q′) may, for example, mark the same quantile for probabilities and divergences, respectively. As an example, we distinguish 2×2=4 cases, e.g. corresponding to FIG. 12a) through d).

FIG. 12 shows an example for probability densities according to embodiments of the invention: The blue curve shows the distribution of the estimated fraction q of test cases with target value t=true for random samples from the overall distribution of test cases, in comparison to the local fraction pᵥ, shown as red line. The distribution mean is Q. Probability q′, shown as black line, indicates the 1-C quantile of distribution qₛ towards pᵥ. The red arrow indicates the statistically significant difference in probability of a true target value. Four examples of scenarios are shown: a) pᵥ is smaller than both qₛ and Q and thus statistically significantly smaller than Q(b) and c) pᵥ is between qₛ and Q and does thus not differ in a statistically significant way from Q. d) pᵥ. is larger than both qₛ and Q and thus statistically significantly larger than( )

When pᵥ<Q we may, for example, be interested in the 1-C quantile and in the largest k′ where

$$Pr ( X \leq {k}^{′} ) \leq 1 - C \qquad ( 19 )$$

holds. The empirical probability q may, for example, be larger than q′=k′|n(v) with confidence (. When pᵥ<q′<Q), see FIG. 12a), the statistically significant divergence d may, for example, be thus

$$d ( v ) = {p}_{v} log \frac{{p}_{v}}{{q}^{′}} + ( 1 - {p}_{v} ) log \frac{1 - {p}_{v}}{1 - {q}^{′}} . \qquad ( 20 )$$

Otherwise, when q′≤pᵥ<Q see e.g. FIG. 12b), there may, for example, be no statistically significant divergence and we may, optionally, set d(v)=0.

When Q≤pᵥ, we may, for example, be interested in the C quantile and in the smallest k′ where

$$Pr ( X \leq {k}^{′} ) \leq C \qquad ( 21 )$$

does not hold. When Q≤pᵥ≤q′, see e.g. FIG. 12c), there may, for example, beno statistically significant divergence and we may set d(v)=0. Otherwise, when Q<q′<pᵥ, see e.g. FIG. 12d), the statistically significant divergence d may, for example, be again given by equation(20).

Section 5: In the following section, an example for a visualization or for a visualization of results of inventive methods according to embodiments is disclosed.

Section 5.1: To start with, examples for plots of interest according to a visualization according to embodiments, are disclosed.

It is to be noted that any or all of the following plot types may be used with or addressed with embodiment of the invention.

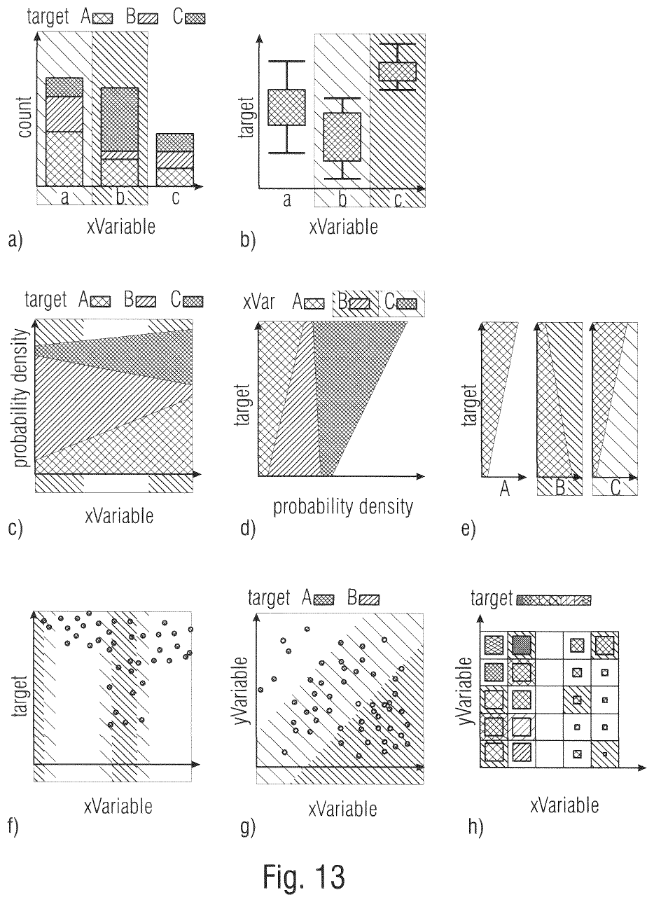

FIG. 13 shows examples according to embodiments for highlighted areas of independent variable(s) for various plot types where the local target distribution differs from its overall distribution according to embodiment of the invention.

Bar charts: The target variable may, for example, always select the stack. See e.g. FIG. 13a. Series, horizontal or vertical split variables may, for example, not be sensible as target variable.

Box plots: The target variable may, for example, always show along the distribution axes. See e.g. FIG. 13b. Series, horizontal or vertical split variables may, for example, not be sensible as target variable.

Distribution plots: The target variable can, for example, either be the discrete stack variable, e.g. as shown in FIG. 13c, or it can, for example, be the (e.g. preferably vertical) continuous distribution axes, e.g. as shown in FIG. 13d and FIG. 13e. Horizontal or vertical split variables may, for example, not be sensible as target variable.

Scatter plots: The target variable can, for example, either be assigned to the y-axis, as shown as an example in FIG. 13f, or to color, e.g. as shown in FIG. 13g. The x-axis may, for example, not be customary as target variable.

Grid plots: The target variable may, for example, always define the grid cell content, as shown as an example in FIG. 13g. The x-axis and y-axis may, for example, not be sensible as target variable.

Section 5.2: In the following, usage of an optional highlight based divergence according to a visualization according to embodiments, is disclosed.

A first proposal, e.g. a first idea according to embodiments is to highlight regions of independent variables where the target distribution differs from the overall target distribution, e.g. in a statistically significant way. As highlight, we propose as an example a yellow background, since yellow may, for example, be commonly used to attract attention. This may, for example, not conflict with brushing which may, for example, use color saturation. Adopting this proposal, however, may, for example, call for avoiding yellow as regular plot color, which may, for example, not be advised anyway, e.g. due to its low contrast to white plot background.

As mentioned before, a yellow background may, for example, indicate a locally deviating target distribution, e.g. measured by the statistically significant divergence, for example, according to equations (11) and (10).

Optionally, for comparable highlighting across plots with the same target variable, many or for example even all currently visible plots should or may use the same divergence-to-saturation mapping.

When hovering over the plot area, a histogram for the local target distribution can, for example, be shown and compared to a histogram for the overall target distribution.

Section 5.3: In the following, an example for Boolean target variables according to a visualization according to embodiments, is disclosed.

For Boolean error variables as target variable, the target distribution may, for example, be fully described by the fraction of true values. To be more informative, we can use a red background (e.g. a background in a first color) where the local error fraction is above average, e.g. pᵥ>Q, and blue background (e.g. a background in a second color) where it is below, e.g. pᵥ<Q.

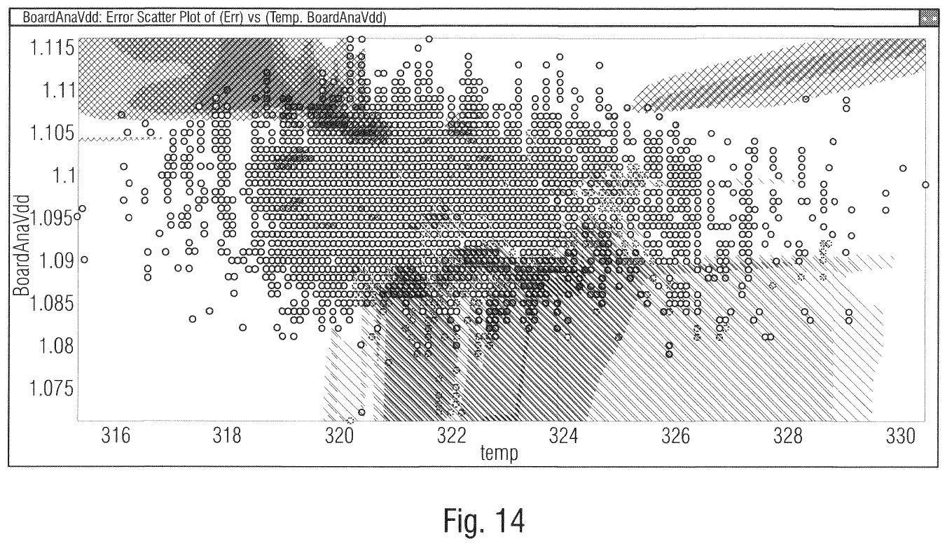

FIG. 14 shows an example of a scatter plot with Boolean target variable (true=error, blue=no error) according to embodiments of the invention. Red/blue background highlights regions of increased/reduced error density. Contrast this to a standard scatter plot in FIG. 10 that visualizes the same data.

Section 5.4: In the following, usage of an optional highlight based on divergence and differing means, according to a visualization according to embodiments, is disclosed.

Optionally, when the local distribution of a continuous target variable diverges from its overall distribution, it may, for example, be interesting to know to which extend the divergence can be explained by a higher or lower mean and/or to which extend the distribution shape may, for example, be different, e.g. independent of a shifted mean.

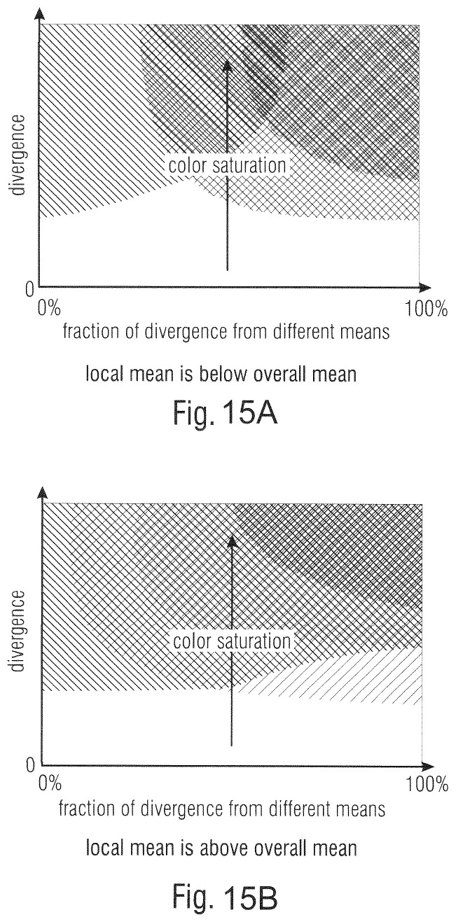

The following highlight coloring with saturation is proposed as an example for such cases, see e.g. FIG. 15 (It is to be noted that following choice of colors is an example. Embodiments may comprise other colors and/or color ranges for visualization):

FIG. 15 shows an example for a highlighting with saturation according to embodiments of the invention: The divergence value controls the saturation(vertical axis), while the fraction of divergence that can be explained by a different mean controls the color, interpolated a) between yellow and blue when the local mean is below the overall mean or b) between yellow and red when the local mean is above the overall mean(example).

Optionally, when the local mean is above average, pᵥ>Q, use the red-yellow-white colormap, e.g. as shown in FIG. 15b. When it is lower, pᵥ<Q, use the blue-yellow-white colormap, e.g. as shown in FIG. 15a. See section 4.4.

The statistically significant divergence value d(v) may, for example, control the color saturation of the highlight color, e.g. ranging from white for zero divergence to fully saturated color, see, as an example, the vertical axes in FIG. 15.

The fraction u of divergence that can, for example, be explained by a shift of the distribution towards higher or lower means may, for example, control an interpolated highlight color between red/blue and yellow, see, as an example the horizontal axes in FIG. 15.

This explanation may, for example, assume a blue-to-red colormap for the continuous target variable but can be adapted to other colors as well. Optionally, however, a colormap may, for example, be recommended that interpolates the continuous target variable between two colors only, e.g., from blue over white to red. Preferably pure white may, for example, encode the average value of the target variable.

A legend may, for example, illustrate the use of red, blue, and yellow. For example, to make highlighting comparable across plots with the same target variable, all visible plots should or may use the same colormap, e.g. according to FIG. 15.

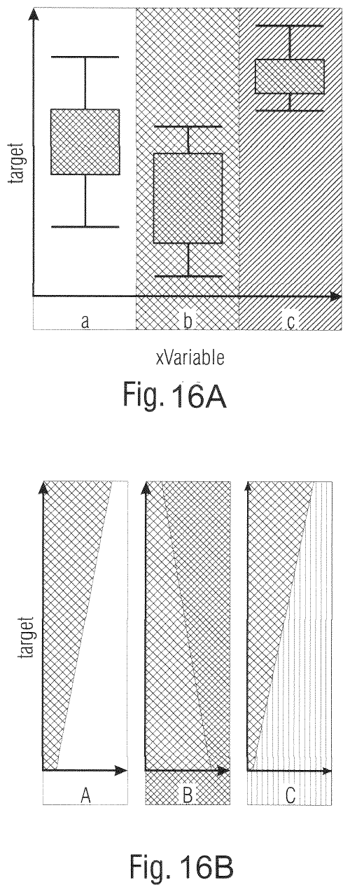

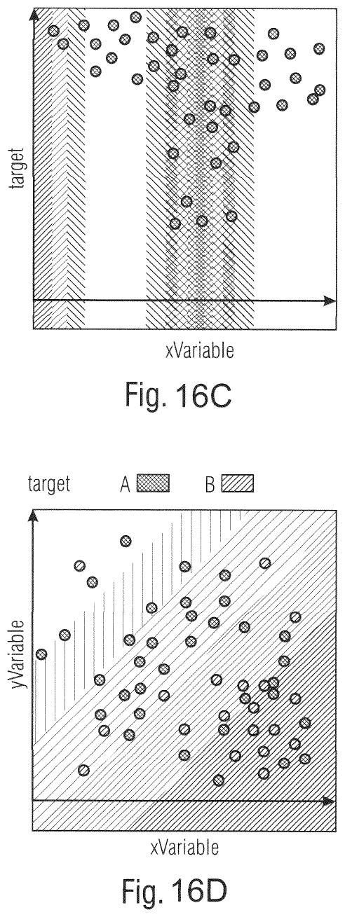

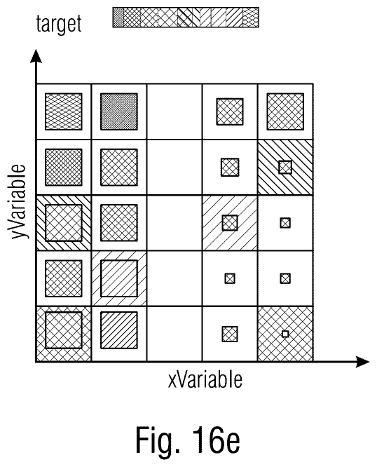

FIG. 16 shows several plot examples according to embodiments of the invention.

FIG. 16: Plot examples where a red background highlights areas where the target value is higher than average, blue where it is lower and yellow where the distribution shape differs, but the mean equals the overall mean.

Note, in plots where blue and red do not encode the target value, see e.g. FIG. 16a-c, the appearance of blue or red may be unexpected. In these cases, it may be better to simply use yellow highlighting (e.g. a one color highlighting), for example as described in section 5.2.

Hence, in general, methods according to embodiments of the invention may comprise visualizing the measurement data and a measurement data meta information, which may, for example, also be considered an extension information, that is based on the statistically significant dissimilarity value, e.g. d(v), wherein a visualization of the measurement data may comprise a representation of the measurement results over the measurement conditions or over corresponding independent variables, e.g. or over corresponding independent variable values and wherein the visualization, e.g. a representation of the measurement results may comprise highlights, wherein the highlights are dependent on, e.g. based on; e.g. associated with, the measurement data meta information, e.g. the corresponding measurement data meta information of the respective measurement results, such that measurement results of corresponding conditional distributions deviating statistically significantly from an overall distribution of the measurement results, or deviating from a sample distribution, e.g. an empirical distribution, of the measurement results, are highlighted and/or such that areas of the visualization associated with measurement results of corresponding conditional distributions deviating statistically significantly from an overall distribution of the measurement results, or deviating from a sample distribution, e.g. an empirical distribution, of the measurement results, are highlighted.

As explained before, optionally, the highlighting may coloring a background of the plot, wherein a saturation of the coloring is determined according to the statistically significant dissimilarity value.

As another optional feature, a color of the coloring may be determined according to a normalized dissimilarity fraction. Alternatively or in addition, a color of the coloring may be determined according to a comparison of an information about an overall distribution of the measurement results and the information about the conditional distribution. Alternatively or in addition, a color of the coloring may be determined according to a comparison of an information about a sample distribution of the measurement results and the information about the conditional distribution.

Optionally, as explained before, but in general words, methods according to embodiments may comprise visualizing the measurement data using the statistically significant dissimilarity value.

Section 6: In the following section, an example for an algorithm according to embodiments is disclosed.

Sections 6.1 and 6.2 will describe two alternative for handling continuous variables according to embodiments. Section 6.3 summarizes an optional example for the computation of statistically significant divergences. Finally, section 6.4 describes an optional example for a fast computation for Boolean target variables.

Section 6.1: In the following, usage of an optional binning of continuous variables, according to an algorithm according to embodiments, is disclosed.

Binning may, for example, be a simple and fast method to discretize continuous variables. We will try to balance the number of value bins between all plot variables—target variable and independent variables—and the average number of hits in value bins. The user can, for example, increase or decrease the number of hits per value bin, e.g., using factor α. 0.1≤α≤10, with default α=1. We may, for example, have to make two obvious exceptions: For categorical variables, we may, for example, always reserve one value bin per categorical value. For discrete numeric variables that can, for example, take M different values, we may, for example, limit the number of value bins to no more than M.

The following example will illustrate an approach according to embodiments: We assume one categorical variable with 5 values, one integer variable with 8 values, 2 continuous variables, N=100,000 test cases and user-specified factor «x=2. Optionally first, we may, for example, split the test cases by the number of categorical value combinations, B_{cat}=5. Each split gets N₁=N/B_{cat}=20,000 test cases. To optionally double the number of hits per value bin, α=2, we may, for example, divide the pool of test cases that will define the number of value bins further, N₂=N₁/α=10,000. These test cases may, for example, be spread across 3 remaining variables (1 discrete, 2 continuous) and the number of hits per value bin, i.e. for example, along

$${B}_{1} = \sqrt[4]{{N}_{2}} = 10$$

This may, for example, lead to H=N₁/B₁³=20 hits per bin, on average. We see that «x=2 has led to H=2B₁, which was the intention. Since the discrete variable takes less than 10 values, we may, for example, assign value bins to all 8 possible values, Bᵢₙₜ=8. The number of remaining test cases per discrete bin may, for example, be now N₃=N₂/Bᵢₙₜ=1,250. These test cases may, for example, now be spread across 3 remaining dimensions. We can, for example, afford

$${B}_{cont} = \sqrt[3]{{N}_{3}} = 10.7 \approx 11.$$

We may, for example, quantize our two continuous variables into B_{cont1}=B_{cont2}=11 equal value bins.

Section 6.2: In the following, usage of local neighborhoods for continuous variables, according to an algorithm according to embodiments, is disclosed.

Binning may, for example, not adapt to the test case density. When we optionally want a smooth background shading along one or multiple continuous axes that adapts to the test case density, such as shown as an example in FIG. 14, we can, for example, gather local statistics from test cases that are closest to points of a relatively fine grid.

For each grid point v, we may, for example, determine the n nearest neighbors, and compare the empirical local target distribution pᵥ(t) of these neighbors with the overall distribution Q(t) as will be described as an example in section 6.3.

We may, for example, determine the number n of nearest neighbors optionally following a similar spirit as described in section 6.2. Let N be the number of all test cases, B the product of value bin numbers for all plot variables, e.g. following section 6.1, for example even when they will later not be discretized, B_{T} the number of bins for the target variable for example even when they will not be discretized. Then the average number of hits per virtual bin may, for example, be H=N/B. We may, for example, optionally choose

$$n = H \cdot {B}_{T} \qquad ( 22 )$$

so that we have enough information about the local target distribution, similar to binning, but now in local neighborhoods.

For one continuous dimension, e.g. like for a distribution plot, finding the nearest neighbors may, for example, be very fast. All that may, for example, be needed may be sorting the target values and picking a range of n test cases, e.g. around each grid point.

Two continuous dimensions, like in a scatter plot, may, for example, require finding the n nearest neighbors for each grid point, which may, for example, be computationally more demanding.

Compared to simple binning, this method may, for example, adapt to the local test case density, may, for example, provide a higher resolution, and may, for example, be visually more appealing. Compared to binning, as an example, only the method for getting local test cases may, for example, be different. Subsequent calculations may, for example, be the same.

Section 6.3: In the following, usage of an optional computing of the statistically significant divergence, according to an algorithm according to embodiments, is disclosed.

Embodiments may comprise any combination of the following steps, hence a method may as an example comprise a subset of the following steps.

Perform a binning 7 for the target variable (optional). E.g. first, compute the overall distribution Q(t) by counting test cases in each target bin t∈ [symbol] . (optional). The following computation may, for example, be performed for each value bin v∈ [symbol] , where a value bin can, for example, represent a value combination of multiple independent variables (optional). Count the number of test cases for each value bin, n(v). (optional). Compute the local target distribution p(t|v). (optional). For s=1 . . . . S draw n(v) random test cases from all test cases, compute the empirical distributions qₛ(1) and divergences I) (v), s=1 . . . . S′ e.g. using equation(10). (optional) Choosing S may, for example, require some experimentation. A good choice may, for example be, or may seem somewhere between 20 and 50. (optional). Sort divergences I), (v), s=1 . . . . S to obtain their cumulative distribution(CDF). (optional) Add Dₛ=0 with probability zero as data point to enable extrapolation of the CDF to small quantiles. (optional). Compute the statistically significant divergence d(v) e.g. by interpolating the cumulative distribution along the divergence axis at cumulative fraction 1-C. (optional) Quadratic interpolation seems or may, for example, be suitable. Again, the choice of the interpolant may, for example require some experimentation.

(optional). Identify sample s′ whose divergence Dₛ, is closest to d and compute its mean-aligned divergence D̅ₛ, e.g. from equation(12) and the mean-induced fraction μ of divergence e.g. from equation(14). (optional)

Section 6.4: In the following an example for Boolean target variables according to an algorithm according to embodiments, is disclosed.

Embodiments may comprise any combination of the following steps, hence a method may as an example comprise a subset of the following steps.

Compute the fraction Q of test cases with target value (=true e.g. in all test cases (optional). The following computation may, for example, be performed for each value bin v∈ [symbol] . (optional). Count the number of test cases for this value bin, n(v). (optional). Compute the fraction pᵥ of local test cases with target value/=true e.g. within all test cases where v∈ [symbol] . (optional)

As an example, if pᵥ<Q:

Compute the 1-C lower quantile k′ for the number of test cases with target value t=true when drawing n(v) randomly selected test cases, where ( ) is the probability of a true target value, see e.g. equations (19) and (17). (optional). Note, Python function stats.binom.ppf may, for example, compute the inverse CDF of a binomial distribution. (optional). Compute q′=k′/n(v). (optional). When pᵥ<q′<Q), compute the statistically significant divergence d(v) e.g. using equation(20), otherwise optionally set d(v)=0. (optional).

Otherwise, if, for example, Q<pᵥ: Compute the (quantile k′. (optional). Compute q′=k′/n(v). (optional). When(<q′<pᵥ, compute the statistically significant divergence d(v) e.g. using equation(20), otherwise optionally set d(v)=0. (optional).

As an example, when pᵥ=Q, set d(v)=0. (optional)

Section 7: In the following embodiments according to the invention will be further discussed.

Section 7.1: To start with, an example for recommended or preferred embodiments according to the invention are disclosed.

Table 1 shows examples for, for example, recommended highlighting for various plot types and data types of the target variable. Yellow highlight may, for example, refer to the scheme described in section 5.2 that is based on divergence optionally only. Red/blue highlight may, for example, refer to the scheme for Boolean target variables, described in section 5.3. Red/blue/yellow highlight may, for example, refer to the scheme described in section 5.4 that is based on the combination of divergence and differing means. Smooth highlighting may, for example, refer to using local neighborhoods from a fine grid e.g. as described in section 6.2. When smoothness is not mentioned for a continuous target variable, binning may, for example, be assumed, e.g. as described in section 6.1.

TABLE 1
Recommended highlighting for various plot types (example)

| | Recommended highlighting |
|---|---|
| Bar chart with series for Boolean target | Error bar matrix |
| | or bar chart with yellow highlight |
| Bar chart with series for categorical target | Yellow highlight |
| Box plot with distribution as target | Yellow highlight (1) |
| Distribution plot with stack as target | Yellow highlight |
| Distribution with continuous target | Smooth yellow highlight (1) |
| Grid plot with Boolean target | Partially filled squares with yellow |
| | highlight |
| Grid plot with categorical target | Yellow highlight |
| Grid plot with continuous target | Partially filled squares with |
| | yellow highlight |
| Scatter plot with y as target | Smooth yellow highlight (2) |
| Scatter plot with red/blue color as Boolean | Smooth red/blue highlight |
| target | |
| Scatter plot with color as categorical target | Smooth yellow highlight |
| Scatter plot with red/blue color as continuous | Smooth red/blue/yellow highlight or |
| target | smooth yellow highlight |

Note
(1): Red/blue may, for example, be no natural colors for this plots.
Note
(2): As an example, since the target variable may, for example, be directly visible along the y-axis, the difference between a shifted mean or a different distribution shape may, for example, be already visible. The more difficult red/blue/yellow highlight may, for example, not be necessary, unless it is desired for consistency.

As an example, when a combined red/blue/yellow highlight is considered to complicated, two separate views can, for example, be considered, one view with yellow highlight (e.g. a first color highlight) and another view with red and blue (e.g. second and third color) only. According to a preferred embodiment, a simple yellow highlight e.g. with a marker tooltip that compares (or may allow to compare) histograms for the local target distribution and the overall target distribution may be used.

Section 7.2: In the following, an optional more fine-grained highlighting according to embodiments of the invention is disclosed.

An alternative idea according to embodiments may, for example, be to highlight each graphical plot element based on statistically significant contributions to mutual information from those test cases that are represented by these graphical plot elements.

Graphical plot elements can, for example, be single stacks in a bar chart, stack slices in a distribution plot, single dots in a scatter plots, or quantile boxes in a box plot. Each test case may, for example, contribute the so-called point mutual information(PMI). Statistically significant PMI can be estimated as the lowest PMI from random data subsets, e.g. with a desired confidence level. When graphical plot elements aggregate values from multiple test cases, their PMI are also aggregated.

As advantage, this method may, for example, provide more fine-grained user attention.

A main advantage of the before mentioned inventive approach, e.g. approaches according to the sections preceding 7.2, may, for example be to mitigate or to overcome the following problem: When, e.g., in a bar chart, a stack vanishes in one of the bars or a stack vanishes locally in a distribution plot—which should definitely be or may be brought to user attention—there may, for example, be no way to highlight the corresponding graphical plot element, because the graphical plot element has disappeared altogether. Second, the highlighted graphical elements might be too small for effective highlighting. In other words, according to before mentioned embodiments, a highlighting may be achieved even in such cases, where using the alternative idea or approach the graphical plot element would have disappeared. In additions, an effective highlighting may be achieved.

Section 7.3: In the following feature names according to embodiments of the invention are disclosed.

Embodiments according to the invention may provide the following functionalities and/or features:
Insight Here
Highlight Insight
Pinpoint Insight
Boost Insight
Show Insight

### REFERENCES

Cover-2006 Thomas M. Cover, Joy A. Thomas: Elements of Information Theory, Wiley 2006
   Further remarks:

Embodiments according to the invention may address plots that are used to understand how a target variable depends on one or multiple independent variables.

Furthermore, embodiments according to the invention may overcome several challenges associated with conventional plots:

Conventional plots may face several challenges for this task:
Large numbers of good cases may hide seldom error cases (this example)
Statistical fluctuations can suggest non-existing dependencies to the user
Visual bias due to non-uniform distribution of samples
Difficulty to estimate fractions (this example) or distributions visually

Embodiments according to the invention may have the following benefits, effects or intention:
Direct user attention to interesting parts
Make (subtle) effects clearly visible that are otherwise hard or impossible to see

Embodiments according to the invention may comprise the following approach, or the approach according to embodiments may comprise the following aspects:
Augment existing plot types
Highlight regions of independent variables (here x/y) where the target distribution differs in a statistically significant way from the overall target distribution.

It should be noted that any embodiments as defined by the claims can be supplemented by any of the details (features and functionalities) described in the above sections.

Also, the embodiments described in the above sections can be used individually, and can also be supplemented by any of the features in another chapter, or by any feature included in the claims.

Also, it should be noted that individual aspects described herein can be used individually or in combination. Thus, details can be added to each of said individual aspects without adding details to another one of said aspects.

Moreover, features and functionalities disclosed herein relating to a method can also be used in an apparatus (configured to perform such functionality). Furthermore, any features and functionalities disclosed herein with respect to an apparatus can also be used in a corresponding method. In other words, the methods disclosed herein can be supplemented by any of the features and functionalities described with respect to the apparatuses.

Also, any of the features and functionalities described herein can be implemented in hardware or in software, or using a combination of hardware and software, as will be described in the section “implementation alternatives”.

### Implementation Alternatives:

Although some aspects are described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus. Some or all of the method steps may be executed by (or using) a hardware apparatus, like for example, a microprocessor, a programmable computer or an electronic circuit. In some embodiments, one or more of the most important method steps may be executed by such an apparatus.

Depending on certain implementation requirements, embodiments of the invention can be implemented in hardware or in software. The implementation can be performed using a digital storage medium, for example a floppv disk, a DVD, a Blu-Ray, a CD, a ROM, a PROM, an EPROM, an EEPROM or a FLASH memory, having electronically readable control signals stored thereon, which cooperate (or are capable of cooperating) with a programmable computer system such that the respective method is performed. Therefore, the digital storage medium may be computer readable.

Some embodiments according to the invention comprise a data carrier having electronically readable control signals, which are capable of cooperating with a programmable computer system, such that one of the methods described herein is performed.

Generally, embodiments of the present invention can be implemented as a computer program product with a program code, the program code being operative for performing one of the methods when the computer program product runs on a computer. The program code may for example be stored on a machine readable carrier.

Other embodiments comprise the computer program for performing one of the methods described herein, stored on a machine readable carrier.

In other words, an embodiment of the inventive method is, therefore, a computer program having a program code for performing one of the methods described herein, when the computer program runs on a computer.

A further embodiment of the inventive methods is, therefore, a data carrier (or a digital storage medium, or a computer-readable medium) comprising, recorded thereon, the computer program for performing one of the methods described herein. The data carrier, the digital storage medium or the recorded medium are typically tangible and/or non-transitionary.

A further embodiment of the inventive method is, therefore, a data stream or a sequence of signals representing the computer program for performing one of the methods described herein. The data stream or the sequence of signals may for example be configured to be transferred via a data communication connection, for example via the Internet.

A further embodiment comprises a processing means, for example a computer, or a programmable logic device, configured to or adapted to perform one of the methods described herein.

A further embodiment comprises a computer having installed thereon the computer program for performing one of the methods described herein.

A further embodiment according to the invention comprises an apparatus or a system configured to transfer (for example, electronically or optically) a computer program for performing one of the methods described herein to a receiver. The receiver may, for example, be a computer, a mobile device, a memory device or the like. The apparatus or system may, for example, comprise a file server for transferring the computer program to the receiver.

In some embodiments, a programmable logic device (for example a field programmable gate array) may be used to perform some or all of the functionalities of the methods described herein. In some embodiments, a field programmable gate array may cooperate with a microprocessor in order to perform one of the methods described herein. Generally, the methods are preferably performed by any hardware apparatus.

The apparatus described herein may be implemented using a hardware apparatus, or using a computer, or using a combination of a hardware apparatus and a computer.

The apparatus described herein, or any components of the apparatus described herein, may be implemented at least partially in hardware and/or in software.

The methods described herein may be performed using a hardware apparatus, or using a computer, or using a combination of a hardware apparatus and a computer.

The methods described herein, or any components of the apparatus described herein, may be performed at least partially by hardware and/or by software.

The described embodiments are merely illustrative for the principles of the present invention. It is understood that modifications and variations of the arrangements and the details described herein will be apparent to others skilled in the art. It is the intent, therefore, to be limited only by the scope of the impending patent claims and not by the specific details presented by way of description and explanation of the embodiments herein.

1-20. (canceled)

21. A method for determining information about characteristics of one or more devices under test (DUTs) using measurement data from an automated test equipment (ATE), the method comprising:
using the ATE to obtain the measurement data from the DUTs, wherein the measurement data comprises a plurality of measurement results and information describing corresponding measurement conditions of the DUTs;
determining information about a conditional distribution of measurement results corresponding to a first subset of the measurement conditions;
determining information about at least one sample distribution, wherein the at least one sample distribution is comparable with the conditional distribution;
determining information about the characteristics of the one or more DUTs by computing a statistically significant dissimilarity value using the information about the conditional distribution and using the information about the at least one sample distribution, and
wherein the information about the characteristics of the one or more DUTs comprises one of: the statistically significant dissimilarity value; and a value that is based on the statistically significant dissimilarity value; and
rendering a visualization of the measurement data and measurement data meta information that is based on the statistically significant dissimilarity value, wherein the visualization comprises highlights that are dependent on the measurement data meta information.

22. The method according to claim 21, further comprising:
determining a plurality of dissimilarity measures between the conditional distribution and respective empirical distributions to form a determination, using the information about the conditional distribution and using the information about a respective empirical distribution; and
determining the statistically significant dissimilarity value using the plurality of dissimilarity measures,
wherein the at least one sample distribution is an empirical distribution,
wherein a number of measurement results considered for the determination of the information about the respective empirical distribution is associated with a number of measurement results considered for the determination of the information about the conditional distribution;
wherein the measurement results of a respective subset of the measurement data is a set of pseudo randomly selected measurement results of the measurement data, and
wherein the determining information about the at least one sample distribution comprises determining an information about a plurality of empirical distributions of measurement results of a plurality of subsets of the measurement data.

23. The method according to claim 22, wherein the statistically significant dissimilarity value is associated with a quantile of a distribution of the plurality of dissimilarity measures, and
further comprising:
determining a cumulative distribution of the plurality of dissimilarity measures; and
determining the statistically significant dissimilarity value, wherein a predetermined portion of the plurality of empirical distributions comprises a dissimilarity measure with respect to the conditional distribution, which is smaller than or equal to the statistically significant dissimilarity value.

24. The method according to claim 21 wherein the visualization of the measurement data comprises a representation of the measurement results over one of: the measurement conditions; and corresponding independent variables.

25. The method according to claim 22, further comprising:
selecting a selected dissimilarity measure of the plurality of dissimilarity measures, wherein the selected dissimilarity measure comprises a smallest deviation to the statistically significant dissimilarity value out of the plurality of dissimilarity measures;
determining a mean value of an empirical distribution corresponding to the selected dissimilarity measure;
determining a mean value of the conditional distribution of the measurement results corresponding to the first subset of the measurement conditions;
determining a mean-aligned dissimilarity measure between the conditional distribution and the empirical distribution corresponding to the selected dissimilarity measure; and
determining an information about a normalized dissimilarity fraction using the mean-aligned dissimilarity measure and the dissimilarity measure between the conditional distribution and the empirical distribution corresponding to the selected dissimilarity measure, and
wherein the information about the characteristics of the one or more DUTs comprises the information about the normalized dissimilarity fraction.

26. The method according to claim 21 further comprising:
determining a mean value of the conditional distribution of the measurement results corresponding to the first subset of measurement conditions; and
determining a mean-aligned dissimilarity measure between the conditional distribution and an overall distribution of the measurement results.

27. The method according to claim 26 further comprising:
determining a dissimilarity measure between the conditional distribution and the overall distribution; and
determining an information about a normalized dissimilarity fraction using the mean-aligned dissimilarity measure and using the dissimilarity measure between the conditional distribution and the overall distribution, and
wherein the information about the characteristics of the one or more DUTs comprises the information about the normalized dissimilarity fraction.

28. The method according to claim 21, further comprising binning measurement data values based on a parameter a, wherein the parameter a influences a number of measurement data that are quantized to a value bin, and
wherein the measurement data comprises one of:
a categorical variable and wherein a respective categorical variable value is associated with one respective value bin;
a discrete variable, and wherein the discrete variable comprises M different values, and wherein the values of the discrete variable are quantized to at most M value bins; and
a continuous variable, and wherein a value of the continuous variable is quantized into a value bin.

29. The method according to claim 28 wherein the measurement data comprises a number of data sets of DUT tests, and
wherein the number of value bins of the measurement data is determined using one or more of the following:
using the number of data sets and using a partitioning based on a number of categorical variables value combinations;
using the number of data sets and using a partitioning based on the parameter a;
using the number of data sets and using a partitioning based on a number of continuous and discrete variables; and
using the number of data sets using a partitioning based on a number of continuous variables.

30. The method according to claim 21, wherein the measurement data comprises the measurement results and values of one or more corresponding independent variables, and further comprising determining the first subset of measurement conditions, wherein measurement conditions of the first subset are neighbored.

31. The method according to claim 21, wherein the measurement data comprises the measurement results and values of one or more corresponding independent variables, and further comprising:
binning values of the measurement data, wherein measurement results or independent variable values of the measurement data are quantized to value bins;
determining an information about an overall distribution of the measurement results based on measurement results of respective value bins;
determining an information about a conditional distribution of measurement results of the first subset of measurement conditions, wherein the first subset of measurement conditions is associated with the independent variable values of a respective value bin;
determining a number of measurement results corresponding to the first subset of measurement conditions;
determining an information about a plurality of empirical distributions of measurement results of a plurality of subsets of the measurement data, wherein a number of measurement results considered for the determining an information about a plurality of empirical distributions of measurement results is equal to the number of measurement results of the first subset of measurement conditions, and wherein the measurement results of a respective subset of the measurement data are a set of pseudo randomly selected measurement results of the measurement data;
determining a plurality of dissimilarity measures between the conditional distribution and respective empirical distributions using the information about the conditional distribution and using the information about the respective empirical distribution;
determining a cumulative distribution of the plurality of dissimilarity measures;
determining the statistically significant dissimilarity value, wherein a predetermined portion of the empirical distributions comprises a dissimilarity measure with respect to the conditional distribution which is smaller than or equal to the statistically significant dissimilarity value;
selecting a selected dissimilarity measure of the plurality of dissimilarity measures, wherein the selected dissimilarity measure comprises a smallest deviation to the statistically significant dissimilarity value out of dissimilarity measures of the plurality of dissimilarity measures;
determining a mean value of the empirical distribution corresponding to the selected dissimilarity measure;
determining a mean value of the conditional distribution of the measurement results corresponding to the first subset of measurement conditions;
determining a mean-aligned dissimilarity measure between the conditional distribution and the empirical distribution corresponding to the selected dissimilarity measure;
determining an information about a normalized dissimilarity fraction using the mean-aligned dissimilarity measure and using the dissimilarity measure between the conditional distribution and the empirical distribution corresponding to the selected dissimilarity measure, and
wherein the information about the characteristics of the DUTs comprises the information about the normalized dissimilarity fraction.

32. The method according to claim 21, wherein a plurality of statistically significant dissimilarity values and a plurality of normalized dissimilarity fractions are determined for different subsets of measurement conditions corresponding to respective value bins.

33. The method according to claim 21, further comprising:
obtaining based on the measurement data, an information about an overall distribution of the measurement results;
comparing the information about the overall distribution and the information about the conditional distribution to generate a first comparison;
wherein the information about the at least one sample distribution is determined based on the first comparison of the information about the overall distribution and the information about the conditional distribution;
comparing the information about the overall distribution, the information about the conditional distribution and the information about the at least one sample distribution to generate a second comparison; and
determining the statistically significant dissimilarity value based on the second comparison.

34. The method according to claim 21, further comprising:
extending the measurement data using the statistically significant dissimilarity value to generate extended measurement data, and
wherein the extended measurement data is a combination of the measurement data itself and associated measurement data meta information, wherein the associated measurement data meta information is determined based on the statistically significant dissimilarity value, and
wherein the measurement data meta information comprises an information about statistically significant dissimilarities between one of: 1) measurement results corresponding to the first subset of measurement conditions and overall measurement results; and 2) measurement results corresponding to the first subset of measurement conditions and measurement results of a selected sample distribution.

35. The method according to claim 21, further comprising:
determining a normalized dissimilarity fraction according to one of:
using a mean-aligned dissimilarity measure;
using a dissimilarity measure between the conditional distribution and an overall distribution of the measurement results, wherein the normalized dissimilarity fraction comprises an information about an amount of the dissimilarity measure that is associated with differing means between the conditional distribution and the overall distribution; and
using a dissimilarity measure between the conditional distribution and a sample distribution of the measurement results, wherein the normalized dissimilarity fraction comprises an information about an amount of the dissimilarity measure that is associated with differing means between the conditional distribution and the sample distribution, and
wherein the measurement data meta information comprises an information about the normalized dissimilarity fraction.

36. The method according to claim 24,
wherein measurement results of corresponding conditional distributions deviating statistically significantly from an overall distribution of the measurement results, or deviating from a sample distribution of the measurement results, are highlighted in the visualization, and
wherein areas of the visualization associated with measurement results of corresponding conditional distributions deviating statistically significantly from an overall distribution of the measurement results, or deviating from a sample distribution of the measurement results, are highlighted in the visualization.

37. The method according to claim 36, wherein the highlights comprise coloring a background of the visualization, wherein a saturation of the coloring is determined according to the statistically significant dissimilarity value.

38. The method according to claim 37, wherein a color of the coloring is determined according to one of:
a normalized dissimilarity fraction;
a comparison of an information about an overall distribution of the measurement results and the information about the conditional distribution; and
a comparison of an information about a sample distribution of the measurement results and the information about the conditional distribution.

39. A non-transitory digital storage medium having a computer program stored therein that when executed performs a method of determining information about characteristics of one or more devices under test (DUTs) using measurement data from an automated test equipment (ATE), the method comprising:
using the ATE to obtain the measurement data from the DUTs, wherein the measurement data comprises a plurality of measurement results and information describing corresponding measurement conditions of the DUTs;
determining information about a conditional distribution of measurement results corresponding to a first subset of the measurement conditions;
determining information about at least one sample distribution, wherein the at least one sample distribution is comparable with the conditional distribution;
determining information about the characteristics of the one or more DUTs by computing a statistically significant dissimilarity value using the information about the conditional distribution and using the information about the at least one sample distribution, and
wherein the information about the characteristics of the one or more DUTs comprises one of: the statistically significant dissimilarity value; and a value that is based on the statistically significant dissimilarity value; and
rendering a visualization of the measurement data and measurement data meta information that is based on the statistically significant dissimilarity value, wherein the visualization comprises highlights that are dependent on the measurement data meta information.

40. An apparatus for determining an information about characteristics of one or more devices under test (DUTs) using measurement data from an automated test equipment (ATE), the apparatus comprising a processor and a memory storing instructions therein, the processor operable to execute the instructions to implement a method comprising:
using the ATE to obtain the measurement data from the DUTs, wherein the measurement data comprises a plurality of measurement results and information describing corresponding measurement conditions of the DUTs;
determining information about a conditional distribution of measurement results corresponding to a first subset of the measurement conditions;
determining information about at least one sample distribution, wherein the at least one sample distribution is comparable with the conditional distribution;
determining information about the characteristics of the one or more DUTs by computing a statistically significant dissimilarity value using the information about the conditional distribution and using the information about the at least one sample distribution, and
wherein the information about the characteristics of the one or more DUTs comprises one of: the statistically significant dissimilarity value; and a value that is based on the statistically significant dissimilarity value; and
rendering a visualization of the measurement data and measurement data meta information that is based on the statistically significant dissimilarity value, wherein the visualization comprises highlights that are dependent on the measurement data meta information.
